(19) United States
(12) Patent Application Publication
(10) Pub. No.: US 2025/0316992 A1
(43) Pub. Date: Oct. 9, 2025

(54) CHARGE MANAGEMENT SYSTEM OF SECONDARY BATTERY

(71) Applicant: Semiconductor Energy Laboratory Co., Ltd., Atsugi-shi, Kanagawa-ken (JP)

(72) Inventors: Takeshi OSADA, Isehara (JP); Yosuke TSUKAMOTO, Atsugi (JP); Kyoichi MUKAO, Odawara (JP); Haruki KATAGIRI, Atsugi (JP)

(21) Appl. No.: 18/878,215

(22) PCT Filed: Jun. 15, 2023
(86) PCT No.: PCT/IB2023/056173

§ 371 Date: Dec. 23, 2024

(30) Foreign Application Priority Data
Jun. 29, 2022 (JP) 2022-104290

(51) Int. Cl. H02J 7/00

(52) U.S. Cl. CPC H02J 7/0014; H02J 7/0029; H02J 7/0048; H02J 7/0063; H02J 7/00714; H02J 7/007182

(57) ABSTRACT

A charge management system of a secondary battery with a novel structure is provided. The charge management system includes the secondary battery including a first battery cell and a second battery cell which are connected in series, a current measurement circuit having a function of measuring current flowing through the first battery cell and the second battery cell in charge of the secondary battery, a voltage measurement circuit having a function of measuring a voltage of each of the first battery cell and the second battery cell in charge of the secondary battery, and a control circuit having a function of performing control for making a charge rate of the first battery cell equal to that of the second battery cell. The control circuit has a function of calculating data exhibiting battery characteristics in accordance with current data and voltage data measured in each of the first battery cell and the second battery cell. The control for making the charge rate of the first battery cell equal to that of the second battery cell is performed by controlling the charge rates so that local maximum values of the data exhibiting battery characteristics are equal to each other.

### TECHNICAL FIELD

One embodiment of the present invention relates to a secondary battery, a charge management method of a secondary battery, and a charge management system of a secondary battery. One embodiment of the present invention relates to a charging method of a secondary battery.

Note that one embodiment of the present invention is not limited to the above technical field. The technical field of the invention disclosed in this specification and the like relates to an object or a method. Alternatively, one embodiment of the present invention relates to a process, a machine, manufacture, or a composition of matter. Thus, more specifically, examples of the technical field of one embodiment of the present invention disclosed in this specification include a display device, a light-emitting device, a power storage device, an imaging device, a memory device, a driving method thereof, and a manufacturing method thereof.

### BACKGROUND ART

Power storage devices (also referred to as batteries or secondary batteries) have been utilized in a wide range of areas from small electronic devices to automobiles. As the application range of batteries expands, there are more and more applications utilizing a multi-cell battery stack that includes a plurality of battery cells connected in series.

The power storage device is provided with a circuit for detecting an abnormality in charge and discharge, such as overdischarge or overcharge. In such a circuit, for example, data of voltage, current, and the like is obtained, and stop of charge and discharge or control of cell balancing or the like is performed on the basis of the obtained data. Thus, the battery can be protected and controlled.

Patent Document 1 discloses a protection IC that functions as a battery protection circuit. Specifically, Patent Document 1 discloses a protection IC that detects an abnormality in charge and discharge by comparing, using a plurality of comparators provided inside, a reference voltage and a voltage of a terminal to which a battery is connected.

### REFERENCE

### Patent Document

[Patent Document 1] Specification of United States Patent Application Publication No. 2011-267726

### SUMMARY OF THE INVENTION

### Problems to be Solved by the Invention

To control cell balancing for uniformizing the amount of electricity (also referred to as capacity or charge capacity) of a plurality of battery cells, it is effective to measure a state of charge (SOC). The SOC, which cannot be directly measured, can be estimated from an SOC-open circuit voltage (OCV) curve by measuring the OCV. However, there is a problem in that measurement of an accurate OCV needs a long time for stabilization of the battery cells.

In the case where the amount of electricity of a plurality of battery cells connected in series is uniformized to control cell balancing while the voltages of terminals of the plurality of battery cells are measured as described above, the plurality of battery cells need to have the same change in the amount of electricity. However, a change in voltage with respect to the amount of electricity of the battery cells is small, and thus a variation in the amount of electricity is sometimes large relative to a variation in voltage. This causes a problem in that a variation in the amount of electricity relative to a variation in voltage is not easily detected without checking the voltage near a full charge, which largely changes with respect to a change in the amount of electricity.

In view of the above, an object of one embodiment of the present invention is to provide a highly reliable secondary battery management system with a novel structure that enables cell balancing. Another object of one embodiment of the present invention is to provide a secondary battery management system with a novel structure that enables cell balancing by estimating a variation in the amount of electricity of battery cells connected in series without waiting for stabilization of the battery cells. Another object of one embodiment of the present invention is to provide a secondary battery management system with a novel structure that enables cell balancing by estimating a state of charge that is hardly affected by a variation in the amount of electricity relative to a variation in voltages of a plurality of battery cells. Another object of one embodiment of the present invention is to provide a secondary battery management system with a novel structure.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. Note that one embodiment of the present invention is to solve at least one of the objects listed above and/or the other objects.

### Means for Solving the Problems

One embodiment of the present invention is a charge management system of a secondary battery including the secondary battery including a first battery cell and a second battery cell which are connected in series, a current measurement circuit having a function of measuring current flowing through the first battery cell and the second battery cell in charge of the secondary battery, a voltage measurement circuit having a function of measuring a voltage of each of the first battery cell and the second battery cell in charge of the secondary battery, and a control circuit having a function of performing control for making a charge rate of the first battery cell equal to that of the second battery cell. The control circuit has a function of calculating data exhibiting battery characteristics in accordance with current data and voltage data measured in each of the first battery cell and the second battery cell. The control for making the charge rate of the first battery cell equal to that of the second battery cell is performed by controlling the charge rates so that local maximum values of the data exhibiting battery characteristics are equal to each other.

In the charge management system of the secondary battery of one embodiment of the present invention, the local maximum values of the data exhibiting battery characteristics are preferably obtained when the vertical axis is dQ/dV representing the amount of change in the amount of electricity with respect to the amount of change in voltage and the horizontal axis is cumulative capacity.

In the charge management system of the secondary battery of one embodiment of the present invention, the local maximum values of the data exhibiting battery characteristics are preferably obtained when the vertical axis is dt/dV representing the amount of change in time with respect to the amount of change in voltage and the horizontal axis is time.

In the charge management system of the secondary battery of one embodiment of the present invention, the secondary battery is preferably charged at a constant current.

Note that other embodiments of the present invention are shown in the description of the following embodiments and the drawings.

### Effect of the Invention

One embodiment of the present invention can provide a highly reliable secondary battery management system with a novel structure that enables cell balancing. Another embodiment of the present invention can provide a secondary battery management system with a novel structure that enables cell balancing by estimating a variation in the amount of electricity of battery cells connected in series without waiting for stabilization of the battery cells. Another embodiment of the present invention can provide a secondary battery management system with a novel structure that enables cell balancing by estimating a state of charge that is hardly affected by a variation in the amount of electricity relative to a variation in voltages of battery cells. Another object of one embodiment of the present invention can provide a secondary battery management system with a novel structure.

Note that the description of these effects does not preclude the existence of other effects. Note that one embodiment of the present invention does not need to have all the effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1B is a block diagram illustrating a charge management system.

FIG. 2 is a flowchart illustrating a charge management system.

FIG. 3 is a schematic diagram illustrating a charge management system.

FIG. 4A to FIG. 4C are schematic diagrams illustrating a charge management system.

FIG. 5 is a flowchart illustrating a charge management system.

FIG. 6 is a schematic diagram illustrating a charge-management system.

FIG. 7A to FIG. 7C are schematic diagrams illustrating a charge management system.

FIG. 8 is a flowchart illustrating a charge management system.

FIG. 9A to FIG. 9C are schematic diagrams illustrating a charge management system.

FIG. 10 is a block diagram illustrating a charge management system.

FIG. 11 is a block diagram illustrating a charge management system.

FIG. 12 is a flowchart illustrating a charge management system.

FIG. 13A is an exploded perspective view of a coin-type secondary battery, FIG. 13B is a perspective view of the coin-type secondary battery, and FIG. 13C is a cross-sectional perspective view thereof.

FIG. 14A illustrates an example of a cylindrical secondary battery. FIG. 14B illustrates the example of the cylindrical secondary battery. FIG. 14C illustrates an example of a plurality of cylindrical secondary batteries. FIG. 14D illustrates an example of a power storage system including a plurality of cylindrical secondary batteries.

FIG. 15A and FIG. 15B illustrate examples of a secondary battery, and FIG. 15C is a diagram illustrating the internal state of a secondary battery.

FIG. 16A to FIG. 16C are diagrams illustrating examples of a secondary battery.

FIG. 17A and FIG. 17B are external views of a secondary battery.

FIG. 18A to FIG. 18C are diagrams illustrating a method for manufacturing a secondary battery.

FIG. 19A to FIG. 19C are diagrams illustrating structure examples of a battery pack.

FIG. 20A is a perspective view of a power storage module of one embodiment of the present invention, FIG. 20B is a block diagram of the power storage module, and FIG. 20C is a block diagram of a vehicle including the power storage module.

FIG. 21A to FIG. 21D are diagrams illustrating examples of transport vehicles. FIG. 21E is a diagram illustrating an example of an artificial satellite.

FIG. 22A and FIG. 22B are diagrams illustrating a power storage device of one embodiment of the present invention.

FIG. 23A is a diagram illustrating an electric bicycle, FIG. 23B is a diagram illustrating a secondary battery of the electric bicycle, and FIG. 23C is a diagram illustrating a scooter.

FIG. 24A to FIG. 24D are diagrams illustrating examples of electronic devices.

FIG. 25A illustrates examples of wearable devices, FIG. 25B is a perspective view of a watch-type device, and FIG. 25C is a diagram illustrating a side surface of the watch-type device.

FIG. 26A and FIG. 26B are graphs illustrating data showing the battery characteristics of battery cells.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

In some cases, the same components, components having similar functions, components made of the same material, components formed at the same time, and the like are denoted by the same reference numerals in the drawings and repeated description of the components having the same reference numerals is omitted in this specification and the like.

In a top view (also referred to as a plan view), a perspective view, and the like, some components might not be illustrated for easy understanding of the drawings.

### Embodiment 1

In this embodiment, a charge management system of a secondary battery of one embodiment of the present invention is described.

### Example 1 of Charge Management System

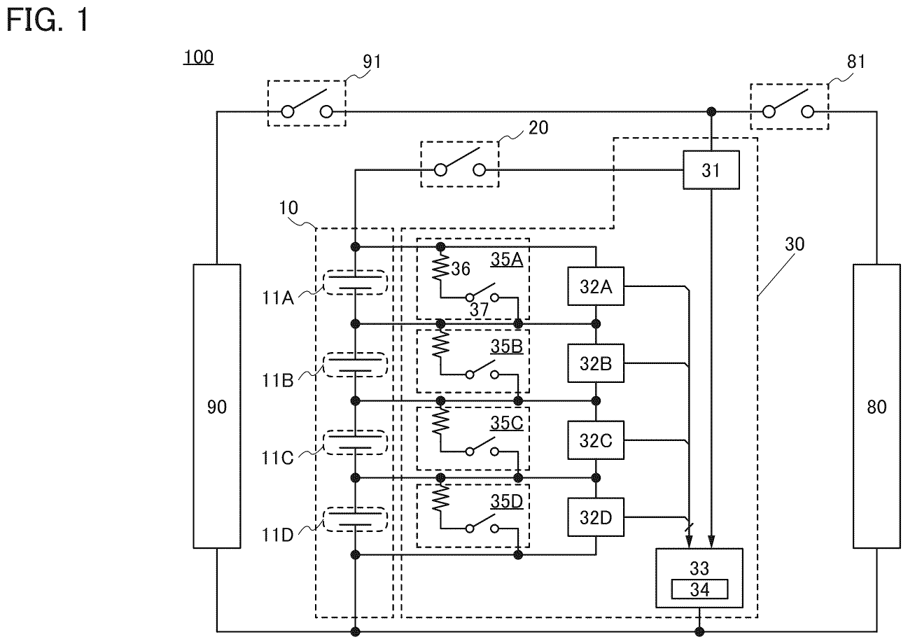

FIG. 1 illustrates an example of a block diagram illustrating the charge management system of one embodiment of the present invention. A charge management system 100 includes a secondary battery 10, a charge/discharge control switch 20, an IC (Integrated Circuit) 30, a load 80, and a charger 90. FIG. 1 also illustrates a discharge switch 81 for controlling current flowing to the load 80 and a charge switch 91 for controlling current flowing from the charger 90.

The secondary battery 10 includes battery cells 11A to 11D connected in series. Note that although the charge management system 100 of one embodiment of the present invention includes four battery cells in this example, the number of battery cells may be two or more. The expression “battery cell 11” is sometimes used for describing the matter common to the battery cells 11A to 11D.

Note that the secondary battery 10 may include a heater and a temperature sensor. The heater and the temperature sensor achieve a structure capable of performing control based on the temperature of the secondary battery 10. For example, a PTC (Positive Temperature Coefficient) thermistor can be used as the heater. As the temperature sensor, for example, an NTC (Negative Temperature Coefficient) thermistor can be used. Another kind of temperature sensor such as a PTC thermistor or a thermocouple may be used as the temperature sensor.

When the discharge switch 81 is controlled, the current of the secondary battery 10 flows to the load 80. The load 80 refers to a CPU, a memory, a display, an inverter, or the like in an electronic device, and a motor, a light, power steering, an inverter, or the like in a vehicle, for example.

When the charge switch 91 is controlled, current for charging the secondary battery 10 is supplied from the charger 90. Examples of the charger 90 include an AC adaptor. The charger 90 may have a function of converting AC power into DC power or a function of converting voltage.

The condition of charge by the charger 90 from the start of charge to the stop of charge is preferably constant current charge. This is because, for example, even if it takes time from determination of the upper limit voltage to the stop of charge, the upper limit voltage is not rapidly changed in the constant current charging period.

The charge/discharge control switch 20 is provided in a path between the secondary battery 10 and the load 80 and a path between the secondary battery 10 and the charger 90. The charge/discharge control switch 20 includes a transistor functioning as a switch, a diode for suppressing a backflow current, and the like. A charge control transistor and a discharge control transistor may be different transistors. The charge or discharge by the charge/discharge control switch 20 is controlled by the IC 30 for cell balancing.

The IC 30 includes a control portion 33 including a memory 34, a current measurement circuit 31, voltage measurement circuits 32A to 32D, and discharge portions 35A to 35D. The number of the voltage measurement circuits 32A to 32D, the number of the discharge portions 35A to 35D, and the number of other components depend on the number of the battery cells 11. The discharge portions 35A to 35D each include a resistor 36 and a cell balance control switch 37.

The IC 30 has a function of mainly performing cell balancing. The IC 30 is also referred to as a cell balancing control IC. The IC 30 may have a function of protecting and controlling the secondary battery 10. The protection function refers to, for example, one or more protection functions of overcharge protection, overdischarge protection, overcharge current protection, overdischarge current protection, and overtemperature protection of the battery cells included in the secondary battery 10. The control function refers to one or more control functions of charge control and discharge control. That is, the IC 30 is a battery control IC.

The IC 30 preferably has a function of an MCU (Micro Controller Unit). In that case, the IC 30 includes a CPU, a memory, a clock generation circuit, an input portion, and an output portion. The input portion and the output portion are collectively referred to as an I/O portion in some cases.

The current measurement circuit 31 has a function of sensing current (charge current) flowing through the battery cells 11A to 11D. The current measurement circuit 31 is also referred to as a current sensor or a current sensing element. As the current measurement circuit 31, a Hall current sensor or a shunt resistor sensor can be used. The current measurement circuit 31 can supply the measured current value (current data) to the control portion 33.

The current measurement circuit 31 preferably also has a function of a coulomb counter. For example, with use of the control portion 33 and the current measurement circuit 31 having the function of a coulomb counter, the cumulative amount of electricity of the secondary battery 10 can be calculated. The calculated amount of electricity allows the amount of electricity charged to the battery cells to be calculated, whereby cell balancing in the battery cells 11A to 11D can be controlled.

The voltage measurement circuits 32A to 32D have a function of sensing terminal voltages (charge voltages) of the battery cells 11A to 11D, respectively. The voltage measurement circuits 32A to 32D may also have a function of measuring terminal voltages (referred to as discharge voltages) at the time of discharge of the battery cells 11A to 11D as well as the voltages at the time of charge. To distinguish the charge voltage from the discharge voltage, for example, a plus sign may be added to the charge voltage, and a minus sign may be added to the discharge voltage. Needless to say, a minus sign may be added to the charge voltage, and a plus sign may be added to the discharge voltage. The expression “voltage measurement circuit 32” is sometimes used for describing the matter common to the voltage measurement circuits 32A to 32D.

The timing of measurement of the terminal voltages by the voltage measurement circuits 32A to 32D can be set at regular intervals, and the regular intervals can be greater than or equal to 80 msec and less than or equal to 10 sec, preferably greater than or equal to 90 msec and less than or equal to 1 sec. A shorter interval allows the states of the battery cells 11A to 11D to be determined with higher accuracy.

The voltage measurement circuits 32A to 32D can supply the measured voltage value (voltage data) to the control portion 33. In the case where the measured voltage value is an analog value, the analog value may be converted into a digital value and then supplied to the control portion 33. That is, the voltage measurement circuits 32A to 32D may each include a circuit that converts an analog value into a digital value, and an analog-digital converter circuit (ADC) can be used as the circuit. The ADC has a configuration of a ΔΣ modulation type, a parallel comparison type (also referred to as a flash type), a pipeline type, or the like. The ΔΣ modulation type ADC has high resolution and thus is suitable for the voltage measuring circuit.

The discharge portions 35A to 35D have a function of discharging the battery cells 11A to 11D, respectively. The discharge portions 35A to 35D are provided so as to be connected in parallel to the battery cells 11A to 11D, respectively. When the cell balance control switches 37 included in the discharge portions 35A to 35D are turned on, current flows to the resistors 36, so that the corresponding battery cells 11A to 11D can be discharged. Whether the discharge portions 35A to 35D perform discharge or not is determined by the control portion 33 for cell balancing. The expression “discharge portion 35” is sometimes used for describing the matter common to the discharge portions 35A to 35D.

In the control portion 33, the measured current value (current data) and voltage value (voltage data) described above are stored in the memory 34 included in the control portion 33 so that the amount of electricity charged to the plurality of battery cells 11 (charge rate) is controlled to be equalized, i.e., cell balancing is controlled. The control portion 33 has a function of calculating data showing the battery characteristics with use of the voltage values of the battery cells 11A to 11D supplied from the voltage measurement circuits 32A to 32D and the current values flowing through the battery cells 11A to 11D supplied from the current measurement circuit 31, so that the amount of electricity of the battery cells 11A to 11D is equalized. Specifically, the control portion 33 has a function of calculating data related to the voltage differential of the amount of electricity (dQ/dV).

The dQ/dV calculated by the control portion 33 can be stored as time-series data in the memory 34. The control portion 33 can analyze the stored dQ/dV time-series data. As the analysis of the dQ/dV time series data, a dQ/dV peak voltage can be calculated. Since the voltage values of the battery cells 11A to 11D are measured by the voltage measurement circuits 32A to 32D, respectively, the control portion 33 can calculate the dQ/dV peak voltages of the battery cells 11A to 11D.

Note that in this specification, the dQ/dV peak voltage refers to a voltage at which the dQ/dV time-series data with a constant voltage width reaches a local maximum value. The voltage width can be, for example, a voltage width of 0.03 V, a voltage width of 0.01 V, or a voltage width of 0.001 V. Note that the peak voltage may be calculated every time the dQ/dV is calculated, or may be calculated every certain period.

With the dQ/dV peak voltage, a change in the crystal structure of a positive electrode active material with a change in the amount of charged electricity can be sensed. Thus, the waveform obtained in charge shows a variation in the amount of electricity charged to the battery cells 11A to 11D. Here, the waveform can have a variety of shapes, for example, a curve, a straight line, and a combined shape of a curve and a straight line. The waveform is not limited to a periodic wave. Examples of the waveform obtained in charge include a dQ/dV-V curve, a dQ/dV-Q curve, and a dt/dV-t curve, which are obtained from data of voltage, time, and current in charge. The charge management system of one embodiment of the present invention senses the extremum of the waveform to estimate a variation in the amount of charged electricity between battery cells and control cell balancing.

In the case where there is a variation in the amount of electricity charged to the battery cells connected in series, measurement of an OCV is effective to estimate the SOC; however, it takes time for the cell batteries to be stabilized in measurement of the OCV. In the case where the amount of electricity of a plurality of battery cells connected in series is uniformized while the voltages of terminals of the battery cells are measured, a variation in the amount of electricity with respect to a variation in voltage becomes large as a change in voltage with respect to the amount of electricity decreases, and thus, a variation in the amount of electricity between battery cells is not easily detected. In one embodiment of the present invention, a change in the crystal structure of a positive electrode active material with a change in the amount of charged electricity is sensed by a dQ/dV peak voltage; hence, even when a change in voltage with a change in the amount of electricity is small, a variation in the amount of charged electricity between battery cells can be estimated to control cell balancing without waiting for the cell batteries to be stabilized.

Note that in the following description of this specification, the structure of performing cell balancing is based on, but is not limited to, the assumption that there is a variation in the amount of electricity charged to battery cells connected in series. For example, the structure of performing cell balancing can be employed on the assumption that there is a variation in the amount of electricity charged to battery cells connected in parallel.

The memory 34 included in the control portion 33 preferably has a table in which the ambient temperature and charge conditions of the battery cells are linked, for example. In the memory 34 included in the control portion 33, charge characteristics linked to the ambient temperature of the battery cells are preferably stored. The charge characteristics may be a past measured value of the battery cell 11, a measured value of another battery cell with similar characteristics, or a waveform obtained by calculation.

The control portion 33 may use the charge characteristics of the battery cells, which are stored in the memory 34, for the analysis of the extrema in the differential curves of voltage and amount of electricity. Here, for example, an amount of electricity-voltage curve, a voltage-dQ/dV curve, a ΔV-t curve, impedance characteristics, or the like can be used as the charge characteristics.

### <Charging Method Example 1>

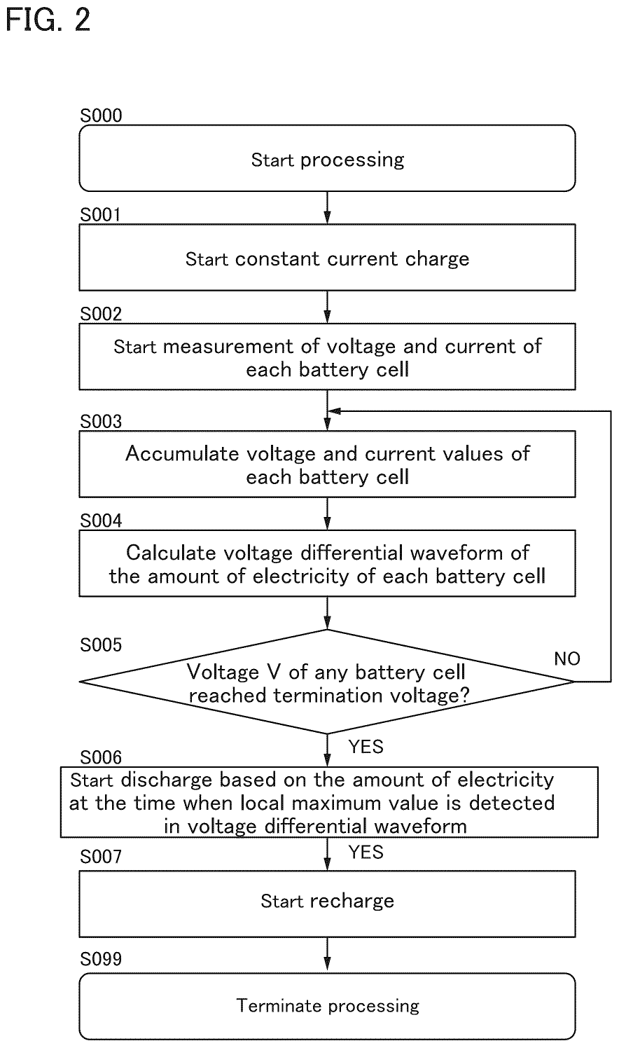

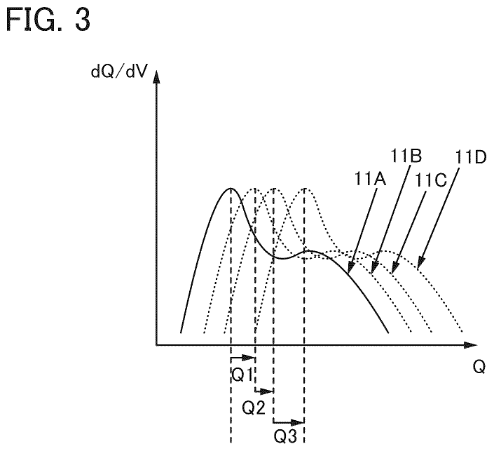

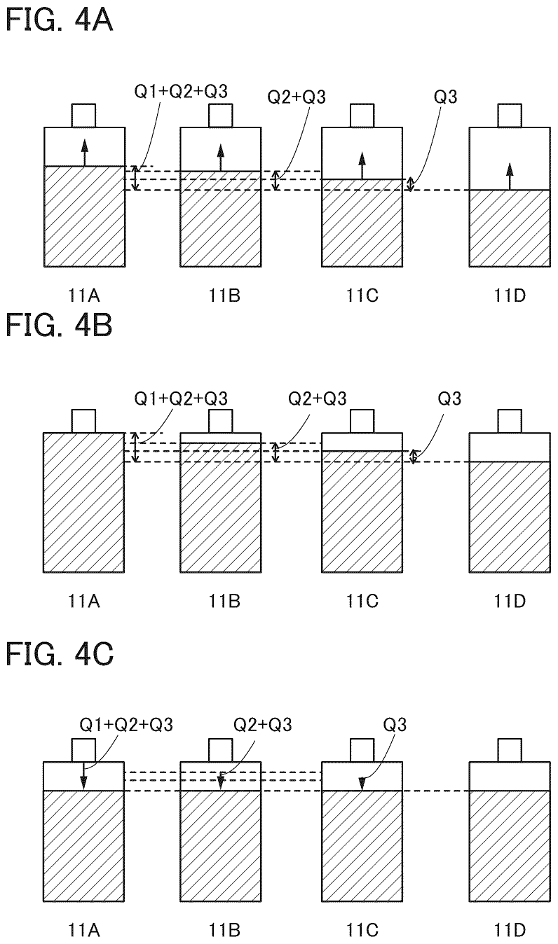

An example of a charging method using the charge management system 100 of the secondary battery of one embodiment of the present invention is described with reference to a flowchart shown in FIG. 2. FIG. 3 schematically illustrates dQ/dV-Q curves in the battery cells 11A to 11D connected in series. FIG. 4A to FIG. 4C are diagrams schematically illustrating changes in the amount of electricity due to control of cell balancing of the battery cells 11A to 11D by the charge management system 100 of the secondary battery.

First, processing is started in Step S000.

Next, in Step S001, the constant current charge of the secondary battery is started. Note that the constant current charge is performed until the charge is stopped.

Next, in Step S002, the voltage measurement circuits 32A to 32D start measurement of voltages of the battery cells 11A to 11D. The control portion 33 measures time using a clock signal or the like. In addition, the current measurement circuit 31 starts measurement of current flowing through the battery cells 11A to 11D. The voltage measurement circuits 32A to 32D supply the measured voltage values to the control portion 33. The current measurement circuit 31 supplies the measured current values to the control portion 33.

Next, in Step S003, the control portion 33 accumulates (stores), as a set of data with time, the voltage values measured by the voltage measurement circuits 32A to 32D and the current values measured by the current measurement circuit 31 after Step S002. The memory 34 or the like included in the control portion 33 can be used for data accumulation. As the time linked to the voltage values and the current values, an elapsed time from the start of charge may be used, for example.

Next, in Step S004, the control portion 33 calculates the dQ/dV of each of the battery cells (the battery cells 11A to 11D), which represents the voltage differential of the amount of electricity, i.e., the amount of change in the amount of electricity with respect to the amount of change in voltage, with use of the set of data of time and the voltage values and current values accumulated at any time. Here, after sets of data of voltage values, current values, and time are accumulated for a predetermined time in Step S003, the voltage differential dQ/dV of each of the battery cells (the battery cells 11A to 11D) may be calculated in Step S004. For example, the sets of data may be accumulated in a period which is long enough to detect the extremum.

Note that the calculation in Step S004 may be performed concurrently with the accumulation (storage) of sets of data performed in Step S003. That is, the calculation can be performed without using the sets of data of time and accumulated voltage values and current values. The values obtained by the calculation are accumulated in the memory 34 or the like included in the control portion 33 for processing based on the waveform of the values. The structure in which the calculated values are accumulated in the memory 34 can reduce the amount of data accumulated in the memory 34.

For example, in curves (hereinafter referred to as dQ/dV-Q curves) estimated for the respective battery cells (the battery cells 11A to 11D) shown in FIG. 3, where the horizontal axis represents the amount of electricity Q and the vertical axis represents the voltage differential dQ/dV of the amount of electricity Q, the battery cells have different extrema (also referred to as peaks), e.g., the local maximum (also referred to as upward convex peak) values here. Note that the amount of electricity on the horizontal axis corresponds to the cumulative amount of electricity (cumulative capacity) in charge. This variation in the amount of electricity, which is caused by a change in the crystal structure of the positive electrode active material, can be confirmed by observation of a change in the amount of electricity in charge. In the battery cell 11B that reaches the local maximum value second after the dQ/dV-Q curve estimated from the battery cell 11A reaches the local maximum value, the amount of electricity is shifted by Q1. In the battery cell 11C that reaches the local maximum value third after the local maximum value of the dQ/dV-Q curve estimated from the battery cell 11B reaches the local maximum value, the amount of electricity is shifted by Q2. In the battery cell 11D that reaches the local maximum value fourth after the dQ/dV-Q curve estimated from the battery cell 11C reaches the local maximum value, the amount of electricity is shifted by Q3. The difference in the amount of electricity between the battery cell 11A and the battery cell 11D is Q1+Q2+Q3. The difference in the amount of electricity between the battery cell 11B and the battery cell 11D is Q2+Q3.

Note that in this embodiment and the like, the local maximum value obtained as the extremum is described as an upward convex peak; however, one embodiment of the present invention is not limited thereto. For example, an extremum attributed to a change in the crystal structure of the positive electrode active material is detected in a waveform obtained at the time of charge of the battery cell. For example, in the case of a waveform of dV/dQ, which is the reciprocal of dQ/dV, the extremum may be a downward convex peak having a local minimum value.

In the dQ/dV-Q curves for the respective battery cells (the battery cells 11A to 11D) shown in FIG. 3, the local maximum values can be detected even when a change in the voltages of the battery cells due to charge is small. That is, the local maximum value can be detected in the state where the amount of electricity obtained by charge is small with respect to the amount of electricity of the battery cell that is fully charged. For example, as schematically illustrated in FIG. 4A, the local maximum value can be detected even with the amount of electricity (hatched parts correspond to the amounts of charged electricity) at the time when a change in voltage during charge is small. Note that in FIG. 4A, upward arrows each indicate an increase in the amount of electricity due to constant current charge.

Next, in Step S005, the control portion 33 determines whether or not the voltage of any of the battery cells reaches a termination voltage (voltage indicating a full charge). For example, as schematically illustrated in FIG. 4B, constant current charge is stopped when the battery cell 11A among the battery cells 11A to 11D is detected (the battery cell filled with a hatched part corresponds to the battery cell that has reached a termination voltage). In the case of constant current charge, the difference in the amount of electricity between the battery cell 11A that has reached a termination voltage and the other battery cells 11B to 11D is equal to the difference in the amount of electricity at the time when the local maximum values are detected in the battery cells 11A to 11D (FIG. 4A). In the case where none of the voltages of the battery cells 11A to 11D reaches the termination voltage, constant current charge is continued and voltage values and current values are accumulated.

Next, in Step S006, the control portion 33 performs discharge based on the difference in the amount of electricity at the time when the local maximum value is detected in the dQ/dV-Q curve. The discharge is performed in accordance with the difference in the amount of electricity obtained by detecting the local maximum values from the dQ/dV-Q curves for the respective battery cells 11A to 11D. For example, as schematically illustrated in FIG. 4C, the difference in the amount of electricity between the battery cell 11A and the battery cell 11D is Q1+Q2+Q3; thus, the battery cell 11A is discharged to be Q1+Q2+Q3 by the control of a discharger 35A. For another example, as schematically illustrated in FIG. 4C, the difference in the amount of electricity between the battery cell 11B and the battery cell 11D is Q2+Q3; thus, the battery cell 11B is discharged to be Q2+Q3 by the control of a discharger 35B. For another example, as schematically illustrated in FIG. 4C, the difference in the amount of electricity between the battery cell 11C and the battery cell 11D is Q3; thus, the battery cell 11C is discharged to be Q3 by the control of a discharger 35C. Note that in FIG. 4C, downward arrows each indicate a decrease in the amount of electricity due to discharge. By thus performing discharge for cell balancing, the battery cells 11A to 11C can have a charge rate with the same amount of electricity as the battery cell 11D.

Then, in Step S007, the battery cells 11A to 11D that have been subjected to cell balancing are started to be recharged with a constant current.

Next, in Step S099, the processing ends.

In the charge management system 100 of the secondary battery, local maximum values can be detected from data showing the battery characteristics of the respective battery cells, and the amount of discharge of each battery cell can be adjusted in accordance with the difference in the detected local maximum value. The data showing the battery characteristics changes with the amount of charged electricity. In the charge management system 100 of the secondary battery, the amount of discharge of each battery cell is adjusted in accordance with the difference in data showing the battery characteristics of the respective battery cells, so that the battery cells connected in series can be subjected to cell balancing.

### <Charging Method Example 2>

Described below is a charging method with a structure different from that of the aforementioned charging method with the charge management system of the secondary battery using a dQ/dV-Q curve.

The dQ/dV can be expressed by the following formula (1).

$$dQ / d V = ( dQ / dt ) \times ( dt / d V ) \qquad ( 1 )$$

In constant current charge, the dQ/dt is constant; thus, the dQ/dV is proportional to the dt/dV. Thus, by evaluating the dt/dV characteristics in the constant current charge, information similar to the dQ/dV characteristics can be obtained.

An example of evaluating the dt/dV characteristics in the region where constant current charge is performed will be described below. In acquisition of the dt/dV characteristics, the current value of the secondary battery is not needed to be acquired every time, and the acquisition of the dt/dV characteristics can be performed more easily than that of the dQ/dV in some cases. In addition, only two parameters of voltage and time are to be acquired, and thus calculation is simple and easy and the circuit scale can be reduced in some cases. Since the amount of data to be acquired can be reduced, the scale of the memory 34 can be reduced in some cases.

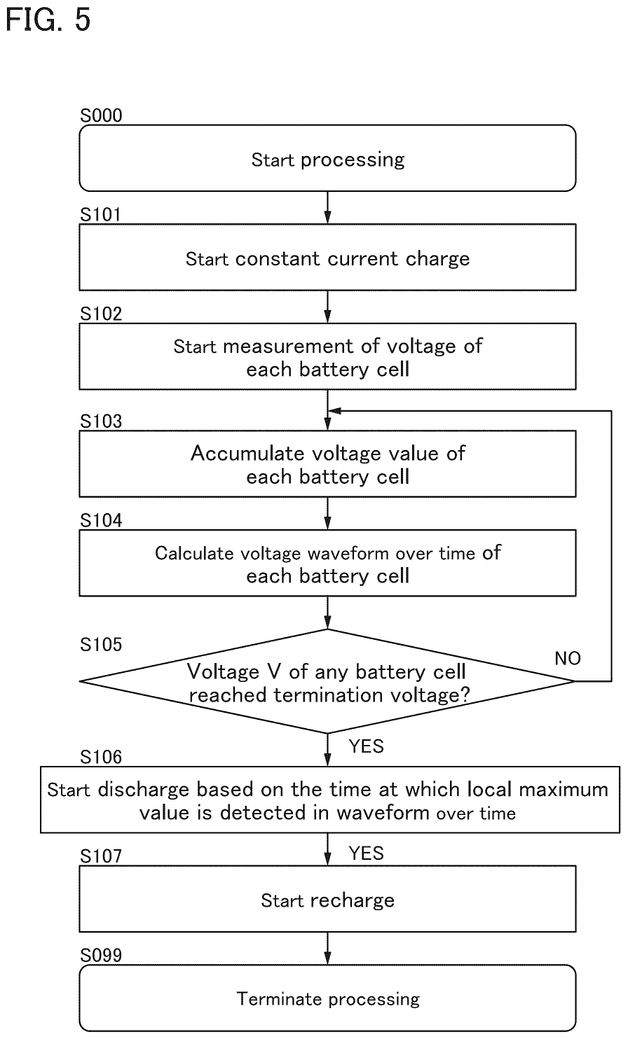

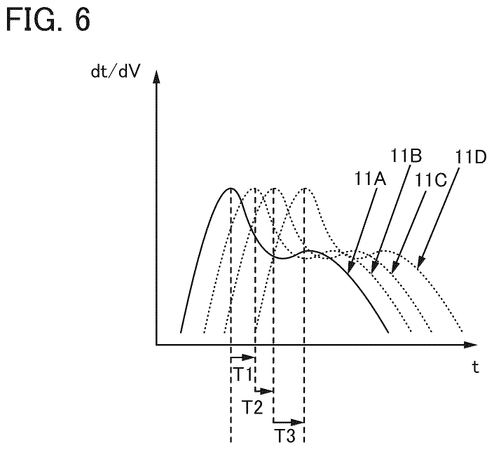

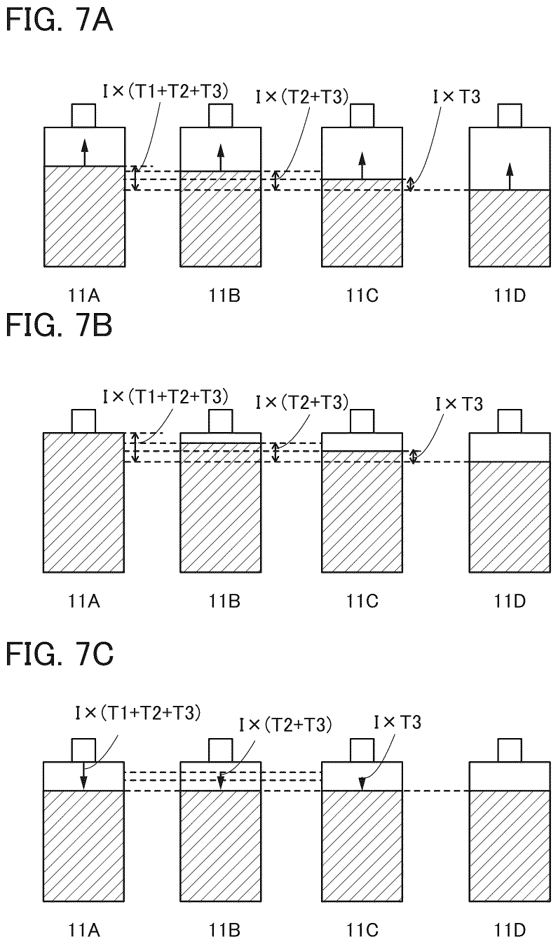

An example of a charging method using the charge management system 100 of the secondary battery of one embodiment of the present invention is described with reference to a flowchart shown in FIG. 5. FIG. 6 schematically illustrates dt/dV-t curves in the battery cells 11A to 11D connected in series. FIG. 7A to FIG. 7C are diagrams schematically illustrating changes in the amount of electricity due to control of cell balancing of the battery cells 11A to 11D by the charge management system 100 of the secondary battery.

First, processing is started in Step S000.

Next, in Step S101, the constant current charge of the secondary battery is started. Note that the constant current charge is performed until the charge is stopped.

Next, in Step S102, the voltage measurement circuits 32A to 32D start measurement of voltages of the battery cells 11A to 11D. The control portion 33 measures the amount of change in time (dt) with respect to the amount of change in voltage (dV) with use of a clock signal or the like. The voltage measurement circuits 32A to 32D supply the measured voltage values to the control portion 33.

Next, in Step S103, the control portion 33 accumulates (stores), as a set of data with time, the voltage values measured by the voltage measurement circuits 32A to 32D after Step S102. The memory 34 or the like included in the control portion 33 can be used for data accumulation. As the time linked to the voltage values, an elapsed time from the start of charge may be used, for example.

Next, in Step S104, the control portion 33 calculates the dt/dV of each of the battery cells (the battery cells 11A to 11D), which is the voltage differential of time, i.e., the amount of change in time with respect to the amount of change in voltage, with use of the set of data of time and the voltage values accumulated at any time. Here, after sets of data of voltage values and time are accumulated for a predetermined time in Step S103, the voltage differential dt/dV of time of each of the battery cells (the battery cells 11A to 11D) may be calculated in Step S104. For example, the sets of data may be accumulated in a period which is sufficient for detection of the extremum.

Note that the aforementioned measurement of the voltage in Step S102 may be performed on one or more of the battery cells 11A to 11D. For example, the voltage measurement may be performed successively in a battery cell (a main battery cell) and intermittently in other battery cells (subsidiary battery cells).

As the main battery cell, for example, the battery cell with the lowest voltage or the battery cell with the highest voltage can be selected from the battery cells immediately after the start of constant current charge (Step S101). Determination of the main battery cell can control the timing of executing Step S103 (accumulation of voltage values of the respective battery cells) described later. For example, in the measurement of the voltage of each battery cell in Step S103, the voltage value of the main battery cell is measured. Then, when the voltage value of the main battery cell is changed by 6 mV, all the voltage values of the subsidiary battery cells are measured, and voltage differential of time, that is, the dt/dV representing the amount of change in time with respect to the amount of change in voltage, is calculated. This structure allows the voltage values of all the battery cells to be measured in accordance with a change in the voltage value of the main battery cell, which facilitates the comparison of the local maximum values of waveforms over time and improves the detection accuracy.

For example, in curves (hereinafter referred to as dt/dV-t curves) estimated for the respective battery cells (the battery cells 11A to 11D) shown in FIG. 6, where the horizontal axis represents time t and the vertical axis represents the voltage differential dt/dV of time t, the battery cells have different extrema (also referred to as peaks), e.g., the local maximum (also referred to as upward convex peak) values here. Note that the time on the horizontal axis corresponds to the cumulative time in charge. This variation in the amount of electricity, which is caused by a change in the crystal structure of the positive electrode active material, can be confirmed by observation of a change in the amount of electricity in charge. In the battery cell 11B that reaches the local maximum value second after the local maximum value of the dt/dV-t curve estimated from the battery cell 11A, the time is shifted by T1. In the battery cell 11C that reaches the local maximum value third after the local maximum value of the dt/dV-t curve estimated from the battery cell 11B, the time is shifted by T2. In the battery cell 11D that reaches the local maximum value fourth after the local maximum value of the dt/dV-t curve estimated from the battery cell 11C, the time is shifted by T3. The difference in the time between the battery cell 11A and the battery cell 11D is (T1+T2+T3). The difference in the time between the battery cell 11B and the battery cell 11D is (T2+T3).

In the dt/dV-t curves for the respective battery cells (the battery cells 11A to 11D) shown in FIG. 6, the local maximum values can be detected in the state where a change in the voltages of the battery cells due to charge is small. That is, the local maximum value can be detected in the state where the amount of electricity obtained by charge is small with respect to the amount of electricity of the battery cell that is fully charged. For example, as schematically illustrated in FIG. 7A, the local maximum value can be detected even with the amount of electricity (hatched parts correspond to the amounts of charged electricity) at the time when a change in voltage during charge is small. Note that in FIG. 7A, upward arrows each indicate an increase in the amount of electricity due to constant current charge. Note that since the constant current charge is performed, the difference in the amount of electricity between battery cells can be estimated to be I (current)×(T1+T2+T3), I (current)×(T2+T3), and I (current)×T3 as shown in the drawing.

Next, in Step S105, the control portion 33 determines whether or not the voltage of any of the battery cells reaches a termination voltage. For example, as schematically illustrated in FIG. 7B, constant current charge is stopped when the battery cell 11A among the battery cells 11A to 11D is detected (the battery cell filled with a hatched part corresponds to the battery cell that has reached a termination voltage). The difference in the amount of electricity between the battery cell 11A that has reached a termination voltage and the other battery cells 11B to 11D is equal to the difference in the amount of electricity at the time when the local maximum values are detected in the battery cells 11A to 11D (FIG. 7A). In the case where none of the voltages of the battery cells 11A to 11D reaches the termination voltage, constant current charge is continued and voltage values are accumulated.

Next, in Step S106, the control portion 33 performs discharge based on the difference in the amount of electricity at the time when the local maximum value is detected in the dt/dV-t curve. The discharge is performed in accordance with the amount of electricity corresponding to the difference in time at which the local maximum value of the dt/dV-t curve is detected. For example, as schematically illustrated in FIG. 7C, the difference in the amount of electricity between the battery cell 11A and the battery cell 11D is IX (T1+T2+T3); thus, the battery cell 11A is discharged to be IX (T1+T2+T3) by the control of the discharger 35A. For another example, as schematically illustrated in FIG. 7C, the difference in the amount of electricity between the battery cell 11B and the battery cell 11D is I×(T2+T3); thus, the battery cell 11B is discharged to be I×(T2+T3) by the control of the discharger 35B. For another example, as schematically illustrated in FIG. 7C, the difference in the amount of electricity between the battery cell 11C and the battery cell 11D is I×T3; thus, the battery cell 11C is discharged to be I×T3 by the control of the discharger 35C. Note that in FIG. 7C, downward arrows each indicate a decrease in the amount of electricity due to discharge. By thus performing discharge for cell balancing, the battery cells 11A to 11C can have a charge rate with the same amount of electricity as the battery cell 11D.

Then, in Step S107, the battery cells 11A to 11D that have been subjected to cell balancing are started to be recharged with a constant current.

Next, in Step S099, the processing ends.

In the charge management system 100 of the secondary battery, local maximum values can be detected from data showing the battery characteristics of the respective battery cells, and the amount of discharge of each battery cell can be adjusted in accordance with the difference in the detected local maximum value. The data showing the battery characteristics changes with the amount of charged electricity. In the charge management system 100 of the secondary battery, the amount of discharge of each battery cell is adjusted in accordance with the difference in data showing the battery characteristics of the respective battery cells, so that the battery cells connected in series can be subjected to cell balancing.

### <Charging Method Example 3>

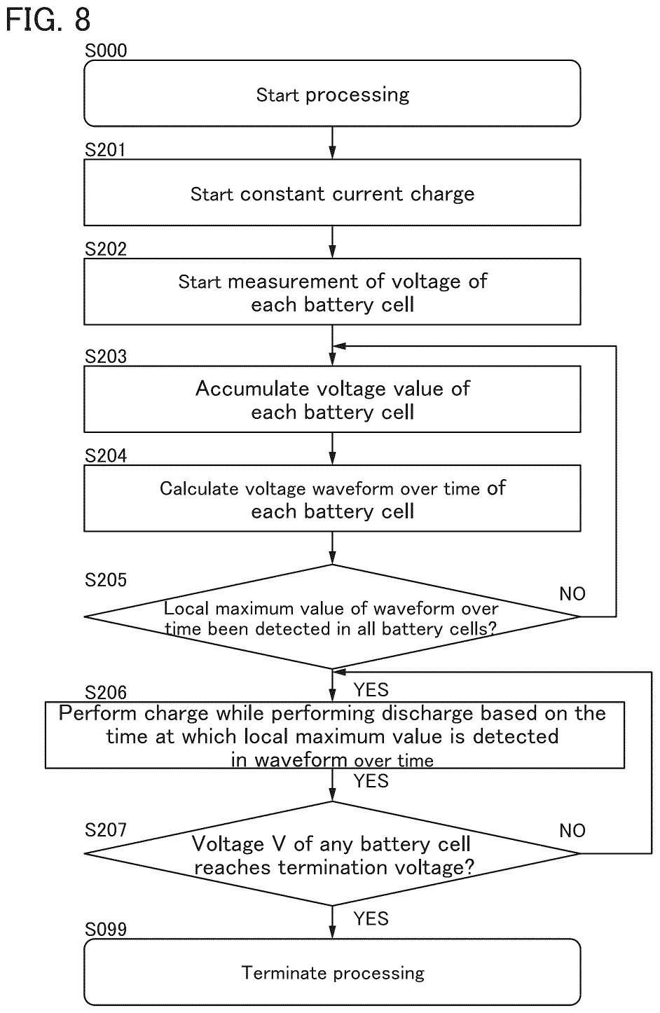

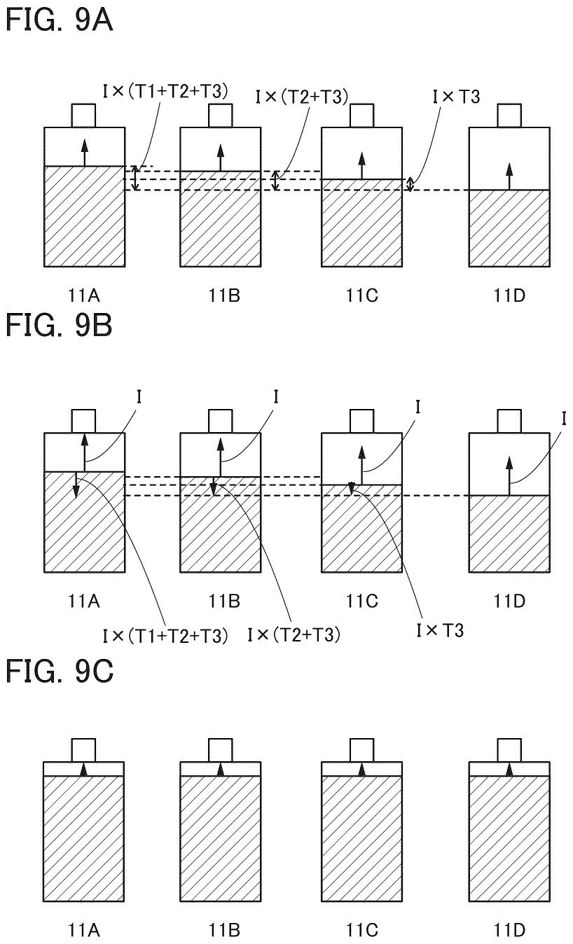

An example of a charging method using the charge management system 100 of the secondary battery of one embodiment of the present invention is described with reference to a flowchart shown in FIG. 8. FIG. 9A to FIG. 9C are diagrams schematically illustrating control of cell balancing of the battery cells 11A to 11D by the charge management system 100 of the secondary battery. Note that data showing battery characteristics corresponding to FIG. 8 and FIG. 9A to FIG. 9C is similar to that in FIG. 6 and the above description is referred to.

First, processing is started in Step S000.

Next, in Step S201, the constant current charge of the secondary battery is started. Note that the constant current charge is performed until the charge is stopped.

Next, in Step S202, the voltage measurement circuits 32A to 32D start measurement of voltages of the battery cells 11A to 11D. The control portion 33 measures time using a clock signal or the like. The voltage measurement circuits 32A to 32D supply the measured voltage values to the control portion 33.

Next, in Step S203, the control portion 33 accumulates (stores), as a set of data with time, the voltage values measured by the voltage measurement circuits 32A to 32D after Step S202. The memory 34 or the like included in the control portion 33 can be used for data accumulation. As the time linked to the voltage values, an elapsed time from the start of charge may be used, for example.

Next, in Step S204, the control portion 33 calculates the voltage differential of time dt/dV of each of the battery cells (the battery cells 11A to 11D) with use of the set of data of time and the voltage values accumulated at any time. Here, after sets of data of voltage values and time are accumulated for a predetermined time in Step S203, the voltage differential dt/dV of time of each of the battery cells (the battery cells 11A to 11D) may be calculated in Step S204. For example, the sets of data may be accumulated in a period which is sufficient for detection of the extremum.

The dt/dV-t curves similar to those in FIG. 6 can be obtained by accumulation of the voltage differential dt/dV. Thus, as illustrated in FIG. 9A, the difference in the amount of electricity between battery cells, which is similar to that in FIG. 7A, can be estimated. Specifically, the difference in the amount of electricity between battery cells can be estimated to be I (current)×(T1+T2+T3), I (current)× (T2+T3), and I (current)× T3 as shown in the drawing.

Next, in Step S205, the control portion 33 determines whether or not the local maximum values are detected in the dt/dV-t curves of all of the battery cells 11A to 11D. In the case where the local maximum value is not detected in any of the battery cells 11A to 11D, constant current charge is continued and voltage values are accumulated.

Next, in Step S206, the control portion 33 performs discharge based on the difference in the amount of electricity at the time when the local maximum value is detected in the dt/dV-t curve, while constant current charge is continued. The discharge is performed in accordance with the amount of electricity corresponding to the difference in time at which the local maximum value of the dt/dV-t curve is detected. For example, as schematically illustrated in FIG. 9B, the difference in the amount of electricity between the battery cell 11A and the battery cell 11D is I×(T1+T2+T3); thus, the battery cell 11A is discharged to be I×(T1+T2+T3) by the control of the discharger 35A. For another example, as schematically illustrated in FIG. 9B, the difference in the amount of electricity between the battery cell 11B and the battery cell 11D is I×(T2+T3); thus, the battery cell 11B is discharged to be I×(T2+T3) by the control of the discharger 35B. For another example, as schematically illustrated in FIG. 9B, the difference in the amount of electricity between the battery cell 11C and the battery cell 11D is I×T3; thus, the battery cell 11C is discharged to be I×T3 by the control of the discharger 35C. Note that in FIG. 9B, downward arrows each indicate a decrease in the amount of electricity due to discharge. Note that in FIG. 9B, upward arrows each indicate an increase in the amount of electricity due to constant current charge (current I). By thus performing discharge for cell balancing while performing charge, the battery cells 11A to 11C can have a charge rate with the same amount of electricity as the battery cell 11D without waiting until any one of the battery cells is fully charged.

Next, in Step S207, the control portion 33 determines whether or not the voltage of any of the battery cells reaches a termination voltage. For example, as schematically illustrated in FIG. 9C, constant current charge is stopped when the battery cell 11A among the battery cells 11A to 11D is detected (the battery cell filled with a hatched part corresponds to the battery cell that has reached a termination voltage). The difference in the amount of electricity between the battery cell 11A that has reached a termination voltage and the other battery cells 11B to 11D is decreased by the discharge operation in Step S206. In the case where none of the voltages of the battery cells 11A to 11D reaches the termination voltage, Step S206 is continued.

Next, in Step S099, the processing ends.

In the charge management system 100 of the secondary battery, local maximum values can be detected from data showing the battery characteristics of the respective battery cells, and the amount of discharge of each battery cell can be adjusted in accordance with the difference in the detected local maximum value. The data showing the battery characteristics changes with the amount of charged electricity. In the charge management system 100 of the secondary battery, the amount of discharge of each battery cell is adjusted in accordance with the difference in data showing the battery characteristics of the respective battery cells, so that the battery cells connected in series can be subjected to cell balancing.

### Example 2 of Charge Management System

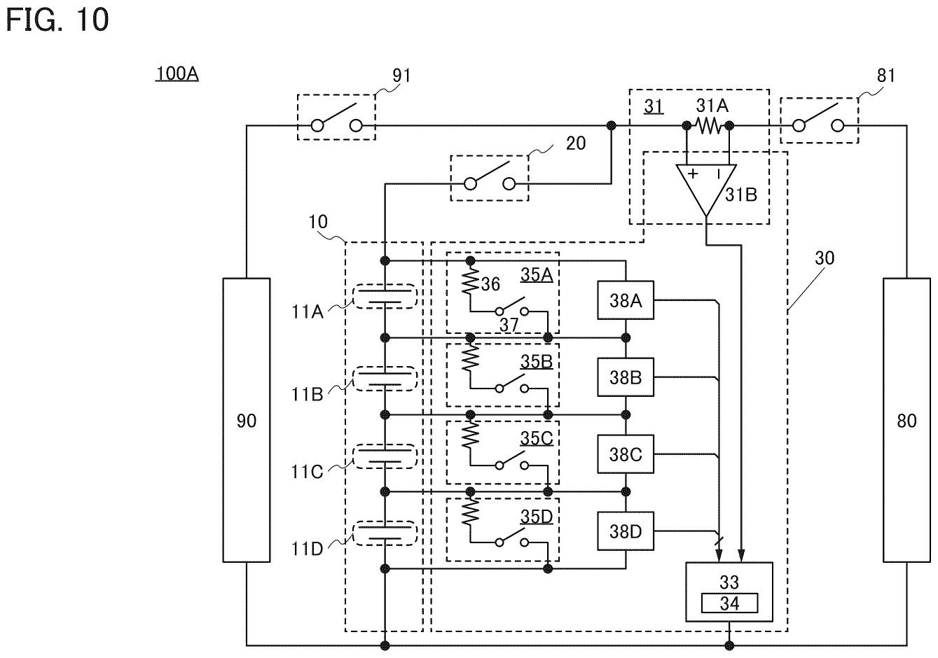

FIG. 10 illustrates an example of a block diagram illustrating the charge management system of one embodiment of the present invention. A charge management system 100A includes the secondary battery 10, the charge/discharge control switch 20, the IC (Integrated Circuit) 30, the load 80, and the charger 90. Note that in the following description in FIG. 10, components common to those in the description in FIG. 1 are not described and denoted by the same reference numerals.

The IC 30 includes the control portion 33 including the memory 34, the current measurement circuit 31, subtractors 38A to 38D, and the discharge portions 35A to 35D. The number of the subtractors 38A to 38D and the number of the discharge portions 35A to 35D depend on the number of the battery cells 11. The expression “subtractor 38” is sometimes used for describing the matter common to the subtractors 38A to 38D.

The current measurement circuit 31 has a function of sensing current (charge current) flowing through the battery cells 11A to 11D. The current measurement circuit 31 includes a resistor 31A and an operational amplifier 31B. As the resistor 31A, a shunt resistor can be used. The resistance value of the shunt resistor is greater than or equal to 10 mΩ and less than or equal to 300 mΩ, preferably greater than or equal to 50 mΩ and less than or equal to 120 mΩ. This structure is preferable because a voltage drop due to the resistor 31A can be amplified by the operational amplifier 31B.

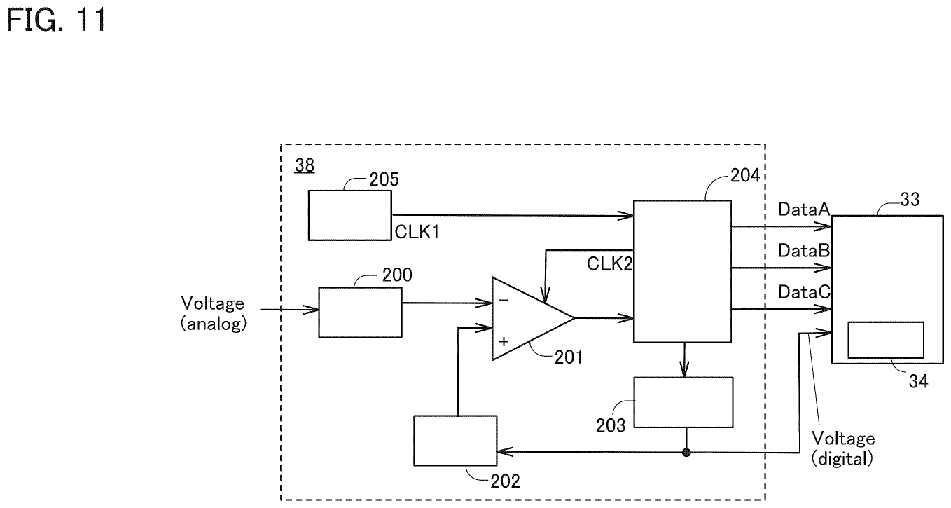

The structure of the subtractor 38 that can be used as the subtractors 38A to 38D is described with reference to FIG. 11.

The subtractor 38 has a function of outputting a time difference and can output a time difference at the time when a difference occurs between the terminal voltage in time t1 and the terminal voltage in time t2, for example. In addition to the above function, the subtractor 38 has a function of converting an analog value into a digital value, that is, a function of an AD converter. Since such a subtractor 38 has a function of measuring voltage, the above-described voltage measurement circuit 32 can be omitted.

The voltage measurement circuit 32 described with reference to FIG. 1 and the like has a structure of converting an input voltage by the AD converter and outputting the voltage to the control portion 33, whereas the subtractor 38 can have a structure of outputting the voltage to the control portion 33 only when the input voltage is changed by a certain voltage ΔV. This allows the control portion 33 to be intermittently operated in a normal state and a standby state, reducing the power consumption of the control portion 33.

In the case of being intermittently operated, the control portion 33 is repeatedly brought into a normal state for controlling cell balancing and a standby state for waiting for a signal corresponding to a change in voltage from the subtractor 38. The subtractor 38 transmits a wake-up signal for transferring the control portion 33 from the standby state to the normal state to bring the control portion 33 into the normal state, and then transmits information of the time dt that has been required for the battery cells 11A to 11D to be changed in voltage. After receiving the information, the control portion 33 is transferred to the standby state again.

FIG. 11 illustrates the control portion 33 in addition to the subtractor 38. The subtractor 38 includes a sample-and-hold circuit 200, a comparator 201, a DA converter 202, a successive approximation register 203, a second control circuit 204, and a clock generation circuit 205. The subtractor 38 can include an AD converter, and the configuration of the AD converter can be any one of a double integrating type, a successive approximation type, a ΔΣ modulation type, a parallel comparison type (also referred to as a flash type), and a pipeline type. The number of bits of the successive approximation type AD converter can be greater than or equal to 10 and less than or equal to 18, and the conversion speed is greater than or equal to several tens of kHz and less than or equal to several MHz, which is preferable. The number of bits of the double integrating type AD converter can be greater than or equal to 8 and less than or equal to 20, and the conversion speed is greater than or equal to several Hz and less than or equal to several kHz, which is preferable.

The subtractor 38 can retain the obtained voltage (analog value) in the sample-and-hold circuit 200. In a period during which the analog value is converted into a digital value, the value is preferably retained in the sample-and-hold circuit 200. As a transistor included in the sample-and-hold circuit 200, an OS transistor can be used. An OS transistor is a transistor in which an oxide semiconductor layer is used as an active layer.

For example, the off-state current value per micrometer of channel width of an OS transistor at room temperature can be lower than or equal to 1 aA (1×10⁻¹⁸ A), lower than or equal to 1 zA (1× 10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude. Such a transistor with a low off-state current is suitable for the sample-and-hold circuit 200.

A value output from the sample-and-hold circuit 200 is input to the comparator 201, and is compared with data output from the successive approximation register 203. The successive approximation register 203 outputs digital data, which is obtained by dividing an analog value of voltage into at least two or more digital values that are allocated to the respective bits. The digital data is converted from digital data into analog data through the DA converter 202 before being input to the comparator 201. In the comparator 201, the data from the sample-and-hold circuit 200 and the data from the successive approximation register 203 are compared. In the case where the two pieces of data match, 0 is output from the comparator 201, and in the case where the two pieces of data do not match, 1 is output from the comparator 201. The value 0 or 1 is output to the second control circuit 204, and in the case where the two pieces of data match, a voltage (digital) is output from the successive approximation register 203. In this manner, the voltage converted into a digital value can be obtained.

Data DataA, data DataB, and data DataC are output from the second control circuit 204 to the control portion 33. The data DataA is a sign (+ or −) representing charge or discharge, for example. The data DataB is count data regarding time, for example. The data DataC is an error flag. As an example of an error that should raise a flag, a case where a difference in voltage is allocated to 1 bit and determined to be two or more bits is given.

The subtractor 38 is preferably capable of outputting time between the time t1 and the time t2. Data corresponding to the time can be output by counting on the basis of a clock signal or the like input to the subtractor 38.

The subtractor 38 is preferably capable of outputting a positive or negative sign. This sign can distinguish the voltage at the time of charge from the voltage at the time of discharge. In the case where there is no need to distinguish the voltages, the sign does not need to be output.

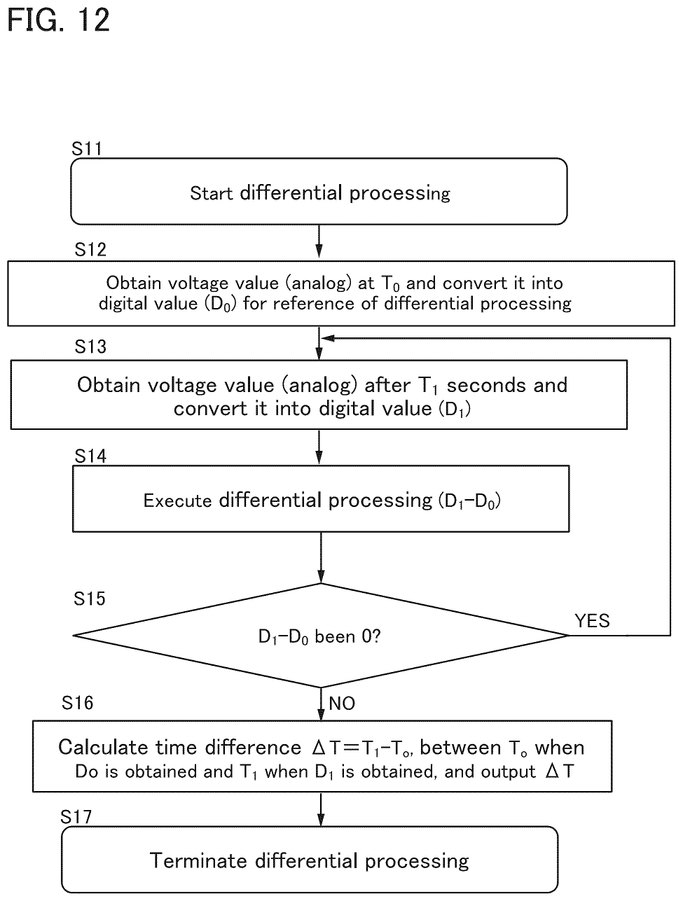

FIG. 12 is a flowchart relating to differential processing.

First, a differential processing is started in Step S11.

Next, in Step S12, an analog voltage value obtained in a given time T₀ can be converted into a digital value (D₀). The information on the obtained time is also added to the voltage value. For the conversion into a digital value, the above-described successive approximation type AD converter is preferably used. This digital value (D₀) is used as a reference for differential processing.

Next, in Step S13, an analog voltage value obtained after T₁ seconds from the given time is converted into a digital value (D₁). The information on the obtained time is also added to the voltage value. Although depending on the specifications of the management system, an interval of T seconds is greater than or equal to 50 ms and less than or equal to 1 s, preferably greater than or equal to 100 ms and less than or equal to 150 ms. The acquisition of the analog voltage value is preferably performed periodically at the intervals mentioned above.

Next, in Step S14, subtraction processing is performed on the digital value (D₀) as a reference and the digital value (D₁) after T seconds, and differential processing is executed.

Next, in Step S15, whether the result of the subtraction processing is a value other than 0 is determined. In the case where the result is not 0 (corresponding to “No” in the chart), the processing proceeds to the next step; in the case where the result is 0 (corresponding to “Yes” in the chart), the processing returns to Step S13, a new voltage value is obtained and converted into a digital value, and then differential processing between the digital value and the digital value (D₀) as a reference voltage is repeated.

In the case where the result is not 0, the processing proceeds to Step S16, and a time difference (ΔT=T₁−T₀) is calculated and output.

After that, the differential processing ends as in Step S17.

A graph relating to battery characteristics, such as a voltage differential waveform, is calculated on the basis of the time difference (ΔT), and cell balancing can be performed as shown in FIG. 2 and the like.

The structure, method, and the like described in this embodiment can be used in an appropriate combination with structures, methods, and the like described in the other embodiments.

### Embodiment 2

This embodiment will describe components included in a lithium-ion battery, which is an example of a battery used as the secondary battery 10. Although not described in this embodiment, a battery other than a lithium-ion battery, for example, a sodium-ion battery, a nickel-hydride battery, or a lead storage battery may be used as the secondary battery 10.

The lithium-ion battery includes a negative electrode, a positive electrode, an electrolyte, a separator, and an exterior body.

### [Negative Electrode]

The negative electrode includes a negative electrode active material layer and a negative electrode current collector. The negative electrode active material layer includes a negative electrode active material and may further include a conductive material and a binder.

Metal foil can be used as the current collector, for example. The negative electrode can be formed by applying slurry onto the metal foil and drying the slurry. Note that pressing may be performed after drying. The negative electrode is a component obtained by forming an active material layer over the current collector.

Slurry refers to a material solution that is used to form the active material layer over the current collector and includes an active material, a binder, and a solvent, preferably also a conductive material mixed therewith. Slurry may also be referred to as slurry for an electrode or active material slurry; in some cases, slurry for forming a negative electrode active material layer is referred to as slurry for a negative electrode.

### <Negative Electrode Active Material>

As the negative electrode active material, for example, a carbon material or an alloy-based material can be used.

As the carbon material, for example, graphite (natural graphite and artificial graphite), graphitizing carbon (soft carbon), non-graphitizing carbon (hard carbon), carbon fiber (carbon nanotube), graphene, carbon black, or the like can be used.

Examples of graphite include artificial graphite and natural graphite. Examples of artificial graphite include mesocarbon microbeads (MCMB), coke-based artificial graphite, and pitch-based artificial graphite. As artificial graphite, spherical graphite having a spherical shape can be used. For example, MCMB is preferably used because it may have a spherical shape. Moreover, MCMB may preferably be used because it can relatively easily have a small surface area. Examples of natural graphite include flake graphite and spherical natural graphite.

Graphite has a low potential substantially equal to that of lithium metal (higher than or equal to 0.05 V and lower than or equal to 0.3 V vs. Li/Li⁺ when lithium ions are inserted into graphite (while a lithium-graphite intercalation compound is formed). For this reason, a lithium-ion battery using graphite can have a high operating voltage. In addition, graphite is preferred because of its advantages such as a relatively high capacity per unit volume, relatively small volume expansion, low cost, and a higher level of safety than that of lithium metal.

Non-graphitizing carbon can be obtained by baking a synthetic resin such as a phenol resin, and an organic substance of plant origin, for example. In non-graphitizing carbon contained in the negative electrode active material of the lithium-ion battery of one embodiment of the present invention, the interplanar spacing of a (002) plane, which is measured by X-ray diffraction (XRD), is preferably greater than or equal to 0.34 nm and less than or equal to 0.50 nm, further preferably greater than or equal to 0.35 nm and less than or equal to 0.42 nm.

As the negative electrode active material, an element that enables charge and discharge reactions by an alloying reaction and a dealloying reaction with lithium can be used. For example, a material containing at least one of silicon, tin, gallium, aluminum, germanium, lead, antimony, bismuth, silver, zinc, cadmium, indium, and the like can be used. Such elements have a higher capacity than carbon. In particular, silicon has a high theoretical capacity of 4200 mAh/g. For this reason, silicon is preferably used as the negative electrode active material. Alternatively, a compound containing any of the above elements may be used. Examples of the compound include SiO, Mg₂Si, Mg₂Ge, SnO, SnO₂, Mg₂Sn, SnS₂, V₂Sn₃, FeSn₂, CoSn₂, Ni₃Sn₂, Cu₆Sn₅, Ag₃Sn, Ag₃Sb, Ni₂MnSb, CeSb₃, LaSn₃, La₃Co₂Sn₇, CoSb₃, InSb, and SbSn. Here, an element that enables charge and discharge reactions by alloying and dealloying reactions with lithium and a compound containing the element, for example, are referred to as alloy-based materials in some cases.

In this specification and the like, “SiO” refers, for example, to silicon monoxide. SiO can alternatively be expressed as SiOₓ. Here, it is preferable that x be 1 or have an approximate value of 1. For example, x is preferably greater than or equal to 0.2 and less than or equal to 1.5, further preferably greater than or equal to 0.3 and less than or equal to 1.2.

As the negative electrode active material, an oxide such as titanium dioxide (TiO₂), lithium titanium oxide (Li₄TisO₁₂), a lithium-graphite intercalation compound (LiₓC₆), niobium pentoxide (Nb₂O₅), tungsten oxide (WO₂), or molybdenum oxide (MoO₂) can be used.

Alternatively, as the negative electrode active material, Li₃₋ₓMₓN (M=Co, Ni, or Cu) with a Li₃N structure, which is a composite nitride of lithium and a transition metal, can be used. For example, Li_{2.6}Co_{0.4}N₃ is preferable because of its high discharge capacity (900 mAh/g and 1890 mAh/cm³).

A composite nitride of lithium and a transition metal is preferably used, in which case lithium ions are contained in the negative electrode active material and thus the negative electrode active material can be used in combination with a positive electrode active material that does not contain lithium ions, such as V₂O₅ or Cr₃O₈. Note that in the case of using a material containing lithium ions as a positive electrode active material, the composite nitride of lithium and a transition metal can be used as the negative electrode active material by extracting the lithium ions contained in the positive electrode active material in advance.

A material that causes a conversion reaction can be used as the negative electrode active material. For example, a transition metal oxide that does not form an alloy with lithium, such as cobalt oxide (CoO), nickel oxide (NiO), or iron oxide (FeO), may be used as the negative electrode active material. Other examples of the material that causes a conversion reaction include oxides such as Fe₂O₃, CuO, Cu₂O, RuO₂, and Cr₂O₃, sulfides such as CoS_{0.89}, NiS, and CuS, nitrides such as Zn₃N₂, Cu₃N, and Ge₃N₄, phosphides such as NiP₂, FeP₂, and CoP₃, and fluorides such as FeF₃ and BiF₃.

Note that one kind of negative electrode active material among the negative electrode active materials shown above can be used; alternatively, a plurality of kinds can be used in combination. For example, a combination of a carbon material and silicon or a combination of a carbon material and silicon monoxide can be used.

As another mode of the negative electrode, a negative electrode that does not contain a negative electrode active material at the completion of the fabrication of the battery may be used. As the negative electrode that does not contain a negative electrode active material, for example, a negative electrode can be used in which only a negative electrode current collector is included at the completion of the fabrication of the battery and in which lithium ions extracted from the positive electrode active material due to charge of the battery are deposited as lithium metal over the negative electrode current collector and form the negative electrode active material layer. A battery including such a negative electrode is referred to as a negative electrode-free (anode-free) battery, a negative electrodeless (anodeless) battery, or the like in some cases.

In the case where the negative electrode that does not contain a negative electrode active material is used, a film for making lithium deposition uniform may be provided over the negative electrode current collector. For the film for making lithium deposition uniform, for example, a solid electrolyte having lithium ion conductivity can be used. As the solid electrolyte, a sulfide-based solid electrolyte, an oxide-based solid electrolyte, a polymer-based solid electrolyte, or the like can be used. In particular, the polymer-based solid electrolyte can be uniformly formed as a film over the negative electrode current collector relatively easily, and thus is suitable for the film for making lithium deposition uniform. As another film for making lithium deposition uniform, for example, a metal film that forms an alloy with lithium can be used. As the metal film that forms an alloy with lithium, for example, a magnesium metal film can be used. It is suitable for the film for making lithium deposition uniform because lithium and magnesium form a solid solution in a wide range of compositions.

In the case where the negative electrode that does not contain a negative electrode active material is used, a negative electrode current collector having projections and depressions can be used. In the case where the negative electrode current collector having projections and depressions is used, a depression of the negative electrode current collector becomes a cavity in which lithium contained in the negative electrode current collector is easily deposited, so that the lithium can be inhibited from having a dendrite-like shape when being deposited.

### <Binder>

As the binder, a rubber material such as styrene-butadiene rubber (SBR), styrene-isoprene-styrene rubber, acrylonitrile-butadiene rubber, butadiene rubber, or ethylene-propylene-diene copolymer is preferably used, for example. Fluororubber can also be used as the binder.

As the binder, for example, a water-soluble polymer is preferably used. As the water-soluble polymer, a polysaccharide can be used, for example. As the polysaccharide, starch, a cellulose derivative such as carboxymethyl cellulose (CMC), methyl cellulose, ethyl cellulose, hydroxypropyl cellulose, diacetyl cellulose, or regenerated cellulose, or the like can be used. It is further preferable that such a water-soluble polymer be used in combination with any of the above rubber materials.

Alternatively, as the binder, a material such as polystyrene, poly(methyl acrylate), poly(methyl methacrylate) (PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, polyvinylidene fluoride (PVDF), polyacrylonitrile (PAN), ethylene-propylene-diene polymer, polyvinyl acetate, or nitrocellulose is preferably used.

A plurality of the above-described materials may be used in combination for the binder.

For example, a material having a significant viscosity modifying effect and another material may be used in combination. For example, a rubber material or the like has high adhesion and high elasticity but may have difficulty in viscosity modification when mixed in a solvent. In such a case, a rubber material or the like is preferably mixed with a material having a significant viscosity modifying effect, for example. As a material having a significant viscosity modifying effect, for instance, a water-soluble polymer is preferably used. As a water-soluble polymer having a significant viscosity modifying effect, the above-mentioned polysaccharide, for instance, a cellulose derivative such as carboxymethyl cellulose (CMC), methyl cellulose, ethyl cellulose, hydroxypropyl cellulose, diacetyl cellulose, or regenerated cellulose, starch, or the like can be used.

Note that a cellulose derivative such as carboxymethyl cellulose obtains a higher solubility when converted into a salt such as a sodium salt or an ammonium salt of carboxymethyl cellulose, and thus easily exerts an effect as a viscosity modifier. A high solubility can also increase the dispersibility of an active material or other components in the fabrication of slurry for an electrode. In this specification and the like, cellulose and a cellulose derivative used as a binder of an electrode include salts thereof.

A water-soluble polymer stabilizes the viscosity by being dissolved in water and allows stable dispersion of the active material and another material combined as a binder, such as styrene-butadiene rubber, in an aqueous solution. Furthermore, a water-soluble polymer is expected to be easily and stably adsorbed onto an active material surface because it has a functional group. Many cellulose derivatives, such as carboxymethyl cellulose, have a functional group such as a hydroxyl group or a carboxyl group. Because of functional groups, polymers are expected to interact with each other and cover an active material surface in a large area.

In the case where the binder that covers or is in contact with the active material surface forms a film, the film is expected to serve also as a passivation film to suppress the decomposition of the electrolyte solution. Here, the “passivation film” refers to a film without electrical conductivity or a film with extremely low electrical conductivity, and can inhibit the decomposition of the electrolyte solution at a potential at which a battery reaction occurs when the passivation film is formed on the active material surface, for example. It is further desirable that the passivation film can conduct lithium ions while inhibiting electrical conduction.

### <Conductive Material>

The conductive material is also referred to as a conductivity-imparting agent or a conductive additive, and a carbon material is used as the conductive material. The conductive material is attached between a plurality of active materials, whereby the plurality of active materials are electrically connected to each other, and the conductivity increases. Note that the term “attach” refers not only to a state where an active material and a conductive material are physically in close contact with each other, and includes, for example, the following concepts: the case where covalent bonding occurs, the case where bonding with the Van der Waals force occurs, the case where a conductive material covers part of the surface of an active material, the case where a conductive material is embedded in surface roughness of an active material, and the case where an active material and a conductive material are electrically connected to each other without being in contact with each other.

Active material layers such as the positive electrode active material layer and the negative electrode active material layer preferably contain a conductive material.

For example, one kind or two or more kinds of carbon black such as acetylene black and furnace black, graphite such as artificial graphite and natural graphite, carbon fiber such as carbon nanofiber and carbon nanotube, and a graphene compound can be used as the conductive material.

As the carbon fiber, carbon fiber such as mesophase pitch-based carbon fiber or isotropic pitch-based carbon fiber can be used, for example. As the carbon fiber, carbon nanofiber, carbon nanotube, or the like can also be used. Carbon nanotube can be fabricated by, for example, a vapor deposition method.

A graphene compound in this specification and the like refers to graphene, multilayer graphene, multi graphene, graphene oxide, multilayer graphene oxide, multi graphene oxide, reduced graphene oxide, reduced multilayer graphene oxide, reduced multi graphene oxide, graphene quantum dots, and the like. A graphene compound contains carbon, has a plate-like shape, a sheet-like shape, or the like, and has a two-dimensional structure formed of a six-membered ring composed of carbon atoms. The two-dimensional structure formed of the six-membered ring composed of carbon atoms may be referred to as a carbon sheet. A graphene compound may include a functional group. The graphene compound is preferably bent. The graphene compound may be rounded like carbon nanofiber.

The active material layer may contain, as a conductive material, metal powder or metal fiber of copper, nickel, aluminum, silver, gold, or the like, a conductive ceramic material, or the like.

The content of the conductive material to the total volume of the active material layer is preferably greater than or equal to 1 wt % and less than or equal to 10 wt %, further preferably greater than or equal to 1 wt % and less than or equal to 5 wt %.

Unlike a particulate conductive material such as carbon black, which makes point contact with an active material, the graphene compound is capable of making low-resistance surface contact; accordingly, the electrical conduction between the particulate active material and the graphene compound can be improved with a smaller amount of the graphene compound than that of a normal conductive material. This can increase the proportion of the active material in the active material layer. Accordingly, the discharge capacity of the battery can be increased.

A particulate carbon-containing compound such as carbon black or graphite and a fibrous carbon-containing compound such as carbon nanotube easily enter a microscopic space. A microscopic space means, for example, a region or the like between a plurality of active materials. When a carbon-containing compound that easily enters a microscopic space and a sheet-like carbon-containing compound, such as graphene, that can impart conductivity to a plurality of particles are used in combination, the density of the electrode is increased and an excellent conductive path can be formed. The battery obtained by the fabrication method of one embodiment of the present invention can have high capacity density per volume and stability, and is effective as an in-vehicle battery.

### <Current Collector>

As the current collector, a highly conductive material which does not alloy with a carrier ion of lithium or the like, for example, a metal such as stainless steel, gold, platinum, zinc, iron, copper, aluminum, or titanium, or an alloy thereof can be used. The current collector can have a sheet-like shape, a net-like shape, a punching-metal shape, an expanded-metal shape, or the like as appropriate.

A resin current collector can be used as the current collector. As the resin current collector, for example, a resin current collector including a resin such as polyolefin (e.g., polypropylene or polyethylene), nylon (polyamide), polyimide, vinylon, polyester, acrylic, or polyurethane, and a particulate or fibrous conductive material (also referred to as a conductive filler) can be used.

As the conductive material contained in the resin current collector, a conductive carbon material and one or more of metal materials such as aluminum, titanium, stainless steel, gold, platinum, zinc, iron, and copper can be used. For example, one kind or two or more kinds of carbon black such as acetylene black or furnace black, graphite such as artificial graphite or natural graphite, carbon fiber such as carbon nanofiber or carbon nanotube, graphene, and a graphene compound can be used as the conductive carbon material. Note that in the case where the resin current collector is used as a positive electrode current collector, an antioxidant such as a hindered phenol-based material is further preferably used.

As the carbon fiber, carbon fiber such as mesophase pitch-based carbon fiber or isotropic pitch-based carbon fiber can be used, for example. As the carbon fiber, carbon nanofiber, carbon nanotube, or the like can also be used. Carbon nanotube can be fabricated by, for example, a vapor deposition method.

Note that the average particle diameter of the conductive material contained in the resin current collector can be greater than or equal to 10 nm and less than or equal to 10 μm, and is preferably greater than or equal to 30 nm and less than or equal to 5 μm.

The current collector preferably has a thickness greater than or equal to 5 μm and less than or equal to 30 μm.

Note that a material that does not alloy with carrier ions of lithium or the like is preferably used for the negative electrode current collector.

### [Positive Electrode]

A positive electrode includes a positive electrode active material layer and a positive electrode current collector. The positive electrode active material layer includes a positive electrode active material and may further include at least one of a conductive material and a binder. Note that the positive electrode current collector, the conductive material, and the binder described in [Negative electrode] can be used.

Metal foil can be used as the current collector, for example. The positive electrode can be formed by applying slurry onto the metal foil and drying the slurry. Note that pressing may be performed after drying. The positive electrode is a component obtained by forming an active material layer over the current collector.

Slurry refers to a material solution that is used to form the active material layer over the current collector and includes an active material, a binder, and a solvent, preferably also a conductive material mixed therewith. Slurry may also be referred to as slurry for an electrode or active material slurry; in some cases, slurry for forming a positive electrode active material layer is referred to as slurry for a positive electrode.

### <Positive Electrode Active Material>

As the positive electrode active material, one or more of a composite oxide having a layered rock-salt structure, a composite oxide having an olivine structure, and a composite oxide having a spinel structure can be used.

As the composite oxide having a layered rock-salt structure, one or more of lithium cobalt oxide, lithium nickel-cobalt-manganese oxide, lithium nickel-cobalt-aluminum oxide, and lithium nickel-manganese-aluminum oxide can be used. Note that the composition formula can be represented by LiMlO₂ (M1 is one or more selected from nickel, cobalt, manganese, and aluminum), and a coefficient of the composition formula is not limited to an integer.

As the lithium cobalt oxide, for example, lithium cobalt oxide to which magnesium and fluorine are added can be used. It is preferable to use lithium cobalt oxide to which magnesium, fluorine, aluminum, and nickel are added.

As the lithium nickel-cobalt-manganese oxide, for example, lithium nickel-cobalt-manganese oxide with a ratio such as nickel:cobalt:manganese=1:1:1, 6:2:2, 8:1:1, or 9:0.5:0.5 can be used. As the above-described lithium nickel-cobalt-manganese oxide, for example, lithium nickel-cobalt-manganese oxide to which one or more of aluminum, calcium, barium, strontium, and gallium are added is preferably used.

As the composite oxide having an olivine structure, one or more of lithium iron phosphate, lithium manganese phosphate, lithium cobalt phosphate, and lithium iron manganese phosphate can be used. Note that the composition formula can be represented by LiM2PO₄ (M2 is one or more selected from iron, manganese, and cobalt), and a coefficient of the composition formula is not limited to an integer.

Furthermore, composite oxide having a spinel structure, such as LiMn₂O₄, can be used.

### [Electrolyte]

Examples of the electrolyte are described below. As one mode of the electrolyte, a liquid electrolyte (also referred to as an electrolyte solution) containing a solvent and an electrolyte dissolved in the solvent can be used. The electrolyte is not limited to a liquid electrolyte (electrolyte solution) that is liquid at room temperature, and a solid electrolyte can be used as well. Alternatively, an electrolyte including both a liquid electrolyte that is liquid at room temperature and a solid electrolyte that is a solid at room temperature (such an electrolyte is referred to as a semi-solid electrolyte) can also be used. Note that when the solid electrolyte or the semi-solid electrolyte is used for a bendable battery, employing a structure where part of a stack in the battery includes the electrolyte can maintain the flexibility of the battery.

In the case where a liquid electrolyte is used for a secondary battery, one of ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, and sultone can be used, or two or more kinds thereof can be used in an appropriate combination at an appropriate ratio, for example.

Alternatively, the use of one or more of ionic liquids (normal temperature molten salts) which have features of non-flammability and non-volatility as a solvent of an electrolyte can prevent a secondary battery from exploding or catching fire even when an internal region of a secondary battery shorts out or the temperature in the internal region increases owing to overcharge or the like. An ionic liquid contains a cation and an anion, specifically, an organic cation and an anion. Examples of the organic cation include aliphatic onium cations such as a quaternary ammonium cation, a tertiary sulfonium cation, and a quaternary phosphonium cation, and aromatic cations such as an imidazolium cation and a pyridinium cation. Examples of the anion include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

The secondary battery of one embodiment of the present invention includes, as a carrier ion, an alkali metal ion (e.g., a lithium ion, a sodium ion, or a potassium ion) or an alkaline earth metal ion (e.g., a calcium ion, a strontium ion, a barium ion, a beryllium ion, or a magnesium ion), for example.

In the case where lithium ions are used as carrier ions, the electrolyte contains lithium salt, for example. As the lithium salt, LiPF₆, LiClO₄, LiAsF₆, LiBF₄, LiAlCl₄, LiSCN, LiBr, LiI, Li₂SO₄, Li₂B₁₀Cl₁₀, Li₂B₁₂Cl₁₂, LiCF₃SO₃, LiC₄F₉SO₃, LiC(CF₃SO₂)₃, LiC(C₂F₅SO₂)₃, LiN(CF₃SO₂)₂, LiN(C₄F₉SO₂) (CF₃SO₂), LiN(C₂F₅SO₂)₂, or the like can be used, for example.

For example, an organic solvent described in this embodiment contains ethylene carbonate (EC), ethyl methyl carbonate (EMC), and dimethyl carbonate (DMC). When the total content of the ethylene carbonate, the ethyl methyl carbonate, and the dimethyl carbonate is set to 100 vol %, an organic solvent in which the volume ratio between the ethylene carbonate, the ethyl methyl carbonate, and the dimethyl carbonate is x:y: 100-x-y (where 5≤x≤35 and 0<y<65) can be used. More specifically, an organic solvent containing EC, EMC, and DMC at EC:EMC:DMC=30:35:35 (volume ratio) can be used.

The electrolyte solution is preferably highly purified and contains a small amount of dust particles and elements other than the constituent elements of the electrolyte solution (hereinafter, also simply referred to as “impurities”). Specifically, the weight ratio of impurities to the electrolyte solution is preferably less than or equal to 1%, further preferably less than or equal to 0.1%, still further preferably less than or equal to 0.01%.

In order to form a coating film (Solid Electrolyte Interphase) at the interface between an electrode (active material layer) and the electrolyte solution for the purpose of improvement of the safety or the like, an additive agent such as vinylene carbonate (VC), propane sultone (PS), tert-butylbenzene (TBB), fluoroethylene carbonate (FEC), lithium bis(oxalate) borate (LiBOB), or a dinitrile compound such as succinonitrile or adiponitrile may be added to the electrolyte solution. The concentration of the additive agent in the solvent is, for example, higher than or equal to 0.1 wt % and lower than or equal to 5 wt %.

When a high-molecular material that can gel is contained in the electrolyte, safety against liquid leakage and the like is improved. Typical examples of the gelled high-molecular material include a silicone gel, an acrylic gel, an acrylonitrile gel, a polyethylene oxide-based gel, a polypropylene oxide-based gel, and a gel of a fluorine-based polymer.

As the high-molecular material, for example, a polymer having a polyalkylene oxide structure, such as polyethylene oxide (PEO); PVDF; polyacrylonitrile; a copolymer containing any of them; or the like can be used. For example, PVDF-HFP, which is a copolymer of PVDF and hexafluoropropylene (HFP), can be used. The formed polymer may be porous.

### [Separator]

When the electrolyte includes an electrolyte solution, a separator is placed between the positive electrode and the negative electrode. As the separator, for example, a fiber containing cellulose such as paper; nonwoven fabric; a glass fiber; ceramics; a synthetic fiber using nylon (polyamide), vinylon (polyvinyl alcohol-based fiber), polyester, acrylic, polyolefin, or polyurethane; or the like can be used. The separator is preferably processed into a bag-like shape to wrap one of the positive electrode and the negative electrode.

The separator may have a multilayer structure. For example, an organic material film of polypropylene, polyethylene, or the like can be coated with a ceramics-based material, a fluorine-based material, a polyamide-based material, a mixture thereof, or the like. Examples of the ceramics-based material include aluminum oxide particles and silicon oxide particles. Examples of the fluorine-based material include PVDF and polytetrafluoroethylene. Examples of the polyamide-based material include nylon and aramid (meta-based aramid and para-based aramid).

When the separator is coated with the ceramics-based material, the oxidation resistance is improved; hence, degradation of the separator during high-voltage charge and discharge can be inhibited and thus the reliability of the secondary battery can be improved. When the separator is coated with the fluorine-based material, the separator is easily brought into close contact with an electrode, resulting in high output characteristics. When the separator is coated with the polyamide-based material, in particular, aramid, heat resistance can be improved to improve the safety of the secondary battery.

For example, both surfaces of a polypropylene film may be coated with a mixed material of aluminum oxide and aramid. Alternatively, a surface of a polypropylene film that is in contact with the positive electrode may be coated with a mixed material of aluminum oxide and aramid, and a surface of the polypropylene film that is in contact with the negative electrode may be coated with the fluorine-based material.

With the use of a separator having a multilayer structure, the capacity per volume of the secondary battery can be increased because the safety of the secondary battery can be maintained even when the total thickness of the separator is small.

### [Exterior Body]

For an exterior body included in the secondary battery, a metal material such as aluminum or a resin material can be used, for example. A film-like exterior body can also be used. As the film, for example, it is possible to use a film having a three-layer structure in which a highly flexible metal thin film of aluminum, stainless steel, copper, nickel, or the like is provided over a film formed of a material such as polyethylene, polypropylene, polycarbonate, ionomer, or polyamide, and an insulating synthetic resin film of a polyamide-based resin, a polyester-based resin, or the like is provided over the metal thin film as the outer surface of the exterior body.

The structure, method, and the like described in this embodiment can be used in an appropriate combination with structures, methods, and the like described in the other embodiments.

### Embodiment 3

In this embodiment, examples of the shape of the secondary battery 10 will be described.

### [Coin-Type Secondary Battery]

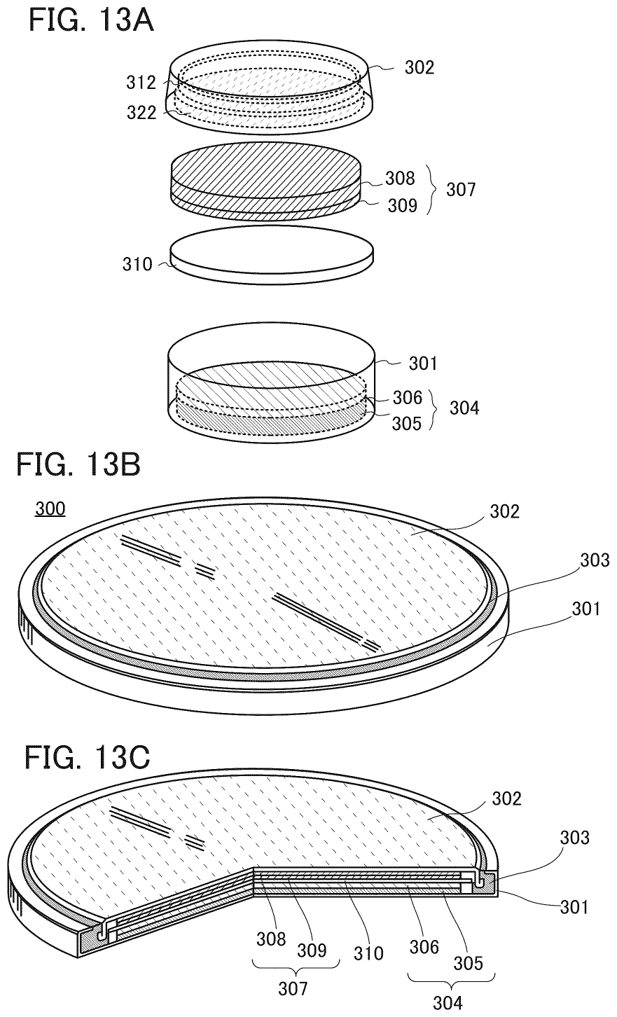

An example of a coin-type secondary battery is described here. FIG. 13A is an exploded perspective view of a coin-type (single-layer flat type) secondary battery, FIG. 13B is an external view thereof, and FIG. 13C is a cross-sectional view thereof. Coin-type secondary batteries are mainly used in small electronic devices.

Note that, for easy understanding, FIG. 13A is a schematic view illustrating overlap (a vertical relation and a positional relation) between components. Thus, FIG. 13A and FIG. 13B do not completely correspond with each other.

In FIG. 13A, a positive electrode 304, a separator 310, a negative electrode 307, a spacer 322, and a washer 312 are overlaid. They are sealed with a negative electrode can 302, a positive electrode can 301, and a gasket. Note that the gasket for sealing is not illustrated in FIG. 13A. The spacer 322 and the washer 312 are used to protect the inside or fix the position inside the cans at the time when the positive electrode can 301 and the negative electrode can 302 are bonded with pressure. For the spacer 322 and the washer 312, stainless steel or an insulating material is used.

The positive electrode 304 has a stacked-layer structure in which a positive electrode active material layer 306 is formed over a positive electrode current collector 305.

FIG. 13B is a perspective view of a completed coin-type secondary battery.

In a coin-type secondary battery 300, the positive electrode can 301 doubling as a positive electrode terminal and the negative electrode can 302 doubling as a negative electrode terminal are insulated from each other and sealed by a gasket 303 made of polypropylene or the like. The positive electrode 304 includes the positive electrode current collector 305 and the positive electrode active material layer 306 provided in contact with the positive electrode current collector 305. The negative electrode 307 includes a negative electrode current collector 308 and a negative electrode active material layer 309 provided in contact with the negative electrode current collector 308. The negative electrode 307 is not limited to having a stacked-layer structure, and lithium metal foil or lithium-aluminum alloy foil may be used.

Note that only one surface of each of the positive electrode 304 and the negative electrode 307 used for the coin-type secondary battery 300 is provided with an active material layer.

For the positive electrode can 301 and the negative electrode can 302, a metal having corrosion resistance to an electrolyte solution, such as nickel, aluminum, or titanium, an alloy of such a metal, or an alloy of such a metal and another metal (e.g., stainless steel) can be used. The positive electrode can 301 and the negative electrode can 302 are preferably covered with nickel, aluminum, or the like in order to prevent corrosion due to the electrolyte solution or the like. The positive electrode can 301 and the negative electrode can 302 are electrically connected to the positive electrode 304 and the negative electrode 307, respectively.

The negative electrode 307, the positive electrode 304, and the separator 310 are immersed in the electrolyte solution. Then, as illustrated in FIG. 13C, the positive electrode 304, the separator 310, the negative electrode 307, and the negative electrode can 302 are stacked in this order with the positive electrode can 301 positioned at the bottom, and the positive electrode can 301 and the negative electrode can 302 are bonded with pressure with the gasket 303 therebetween. In this manner, the coin-type secondary battery 300 is manufactured. In the coin-type secondary battery 300, the positive electrode can 301 and the negative electrode can 302 can be referred to as a positive electrode terminal and a negative electrode terminal, respectively.

With the above-described structure, the coin-type secondary battery 300 can have high discharge capacity and excellent cycle performance.

### [Cylindrical Secondary Battery]

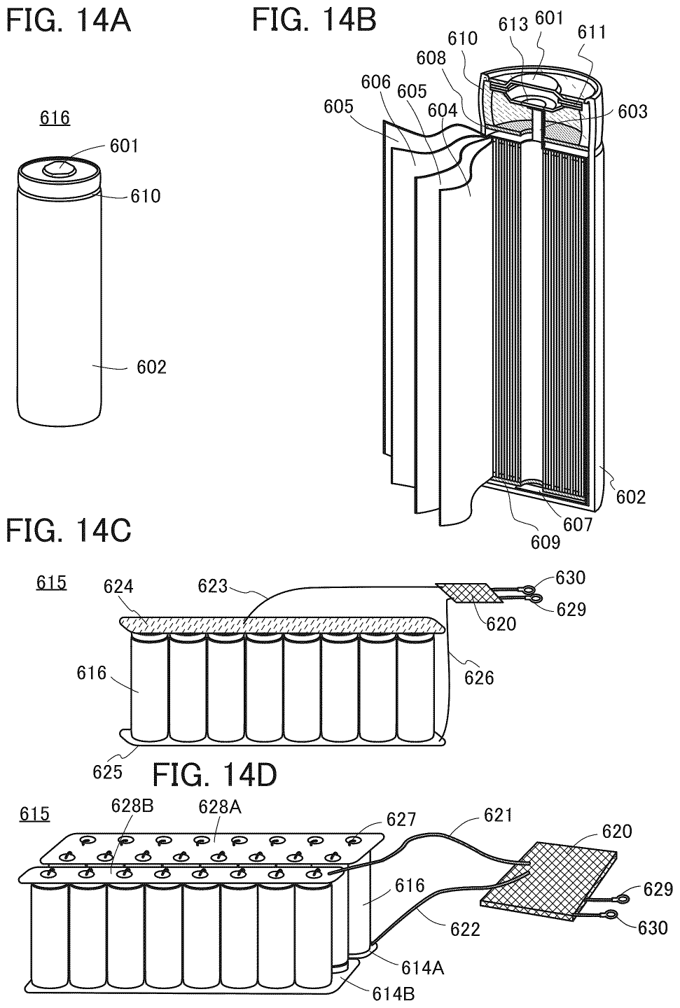

An example of a cylindrical secondary battery is described with reference to FIG. 14A. As illustrated in FIG. 14A, a cylindrical secondary battery 616 includes a positive electrode cap (battery cap) 601 on the top surface and a battery can (outer can) 602 on the side surface and bottom surface. The positive electrode cap 601 and the battery can (outer can) 602 are insulated from each other by a gasket (insulating gasket) 610. In the cylindrical secondary battery 616, the positive electrode cap 601 and the battery can 602 can be referred to as a positive electrode terminal and a negative electrode terminal, respectively.

FIG. 14B schematically illustrates a cross section of the cylindrical secondary battery. The cylindrical secondary battery illustrated in FIG. 14B includes the positive electrode cap (battery cap) 601 on the top surface and the battery can (outer can) 602 on the side surface and bottom surface. The positive electrode cap and the battery can (outer can) 602 are insulated from each other by the gasket (insulating gasket) 610.

Inside the battery can 602 having a hollow cylindrical shape, a battery element in which a strip-like positive electrode 604 and a strip-like negative electrode 606 are wound with a separator 605 located therebetween is provided. Although not illustrated, the battery element is wound around a central axis. One end of the battery can 602 is closed and the other end thereof is opened. For the battery can 602, a metal having corrosion resistance to an electrolyte solution, such as nickel, aluminum, or titanium, an alloy of such a metal, or an alloy of such a metal and another metal (e.g., stainless steel) can be used. The battery can 602 is preferably covered with nickel, aluminum, or the like in order to prevent corrosion due to the electrolyte solution. Inside the battery can 602, the battery element in which the positive electrode, the negative electrode, and the separator are wound is provided between a set of an insulating plate 608 and an insulating plate 609 that face each other. The inside of the battery can 602 provided with the battery element is filled with a nonaqueous electrolyte solution (not illustrated). As the nonaqueous electrolyte solution, a nonaqueous electrolyte solution that is similar to that of the coin-type secondary battery can be used.

Since a positive electrode and a negative electrode that are used for a cylindrical storage battery are wound, active materials are preferably formed on both surfaces of a current collector.

A positive electrode terminal (positive electrode current collecting lead) 603 is connected to the positive electrode 604, and a negative electrode terminal (negative electrode current collecting lead) 607 is connected to the negative electrode 606. Both the positive electrode terminal 603 and the negative electrode terminal 607 can be formed using a metal material such as aluminum. The positive electrode terminal 603 and the negative electrode terminal 607 are resistance-welded to a safety valve mechanism 613 and the bottom of the battery can 602, respectively. The safety valve mechanism 613 is electrically connected to the positive electrode cap 601 through a PTC element (Positive Temperature Coefficient) 611. The safety valve mechanism 613 cuts off electrical connection between the positive electrode cap 601 and the positive electrode 604 when the internal pressure of the battery exceeds a predetermined threshold. The PTC element 611, which is a thermally sensitive resistor whose resistance increases as temperature rises, limits the amount of current by increasing the resistance, in order to prevent abnormal heat generation. Barium titanate (BaTiO₃)-based semiconductor ceramic or the like can be used for the PTC element.

FIG. 14C illustrates an example of a power storage module 615. The power storage module 615 includes a plurality of secondary batteries 616. Positive electrodes of the secondary batteries are in contact with and electrically connected to a conductor 624. Negative electrodes of the secondary batteries are in contact with and electrically connected to a conductor 625. Thus, the conductor 624 can be referred to as a positive electrode terminal of a power storage device (an assembled battery), and the conductor 625 can be referred to as a negative electrode terminal of the power storage device (the assembled battery). The conductor 624 is electrically connected to a control circuit 620 through a wiring 623. The conductor 625 is electrically connected to the control circuit 620 through a wiring 626. As the control circuit 620, a charge and discharge control circuit for performing charge, discharge, and the like or a protection circuit for preventing overcharge and/or overdischarge can be used. The control circuit 620 includes an external terminal 629 and an external terminal 630.

FIG. 14D illustrates an example of the power storage module 615. The power storage module 615 includes the plurality of secondary batteries 616, and the plurality of secondary batteries 616 are sandwiched between a conductive plate 628 (a conductive plate 628A and a conductive plate 628B) and a conductive plate 614 (a conductive plate 614A and a conductive plate 614B). The plurality of secondary batteries 616 are electrically connected to the conductive plate 628 and the conductive plate 614 through a wiring 627. The plurality of secondary batteries 616 may be connected in parallel, connected in series, or connected in series after being connected in parallel. With the power storage module 615 including the plurality of secondary batteries 616, large electric power can be extracted. Note that the plurality of secondary batteries 616 can be referred to as a power storage device or an assembled battery. In this case, a conductive plate having the highest potential between the conductive plate 628 and the conductive plate 614 can be referred to as a positive electrode terminal of the power storage device or a positive electrode terminal of the assembled battery. A conductive plate having the lowest potential between the conductive plate 628 and the conductive plate 614 can be referred to as a negative electrode terminal of the power storage device or a negative electrode terminal of the assembled battery.

A temperature control device may be provided between the plurality of secondary batteries 616. The secondary batteries 616 can be cooled with the temperature control device when overheated, whereas the secondary batteries 616 can be heated with the temperature control device when cooled too much. Thus, the performance of the power storage module 615 is less likely to be influenced by the outside temperature.

In FIG. 14D, the power storage module 615 is electrically connected to the control circuit 620 through a wiring 621 and a wiring 622. The wiring 621 is electrically connected to the positive electrodes of the plurality of secondary batteries 616 through the conductive plate 628, and the wiring 622 is electrically connected to the negative electrodes of the plurality of secondary batteries 616 through the conductive plate 614. The control circuit 620 includes an external terminal 629 and an external terminal 630.

### [Other Structure Examples of Secondary Battery]

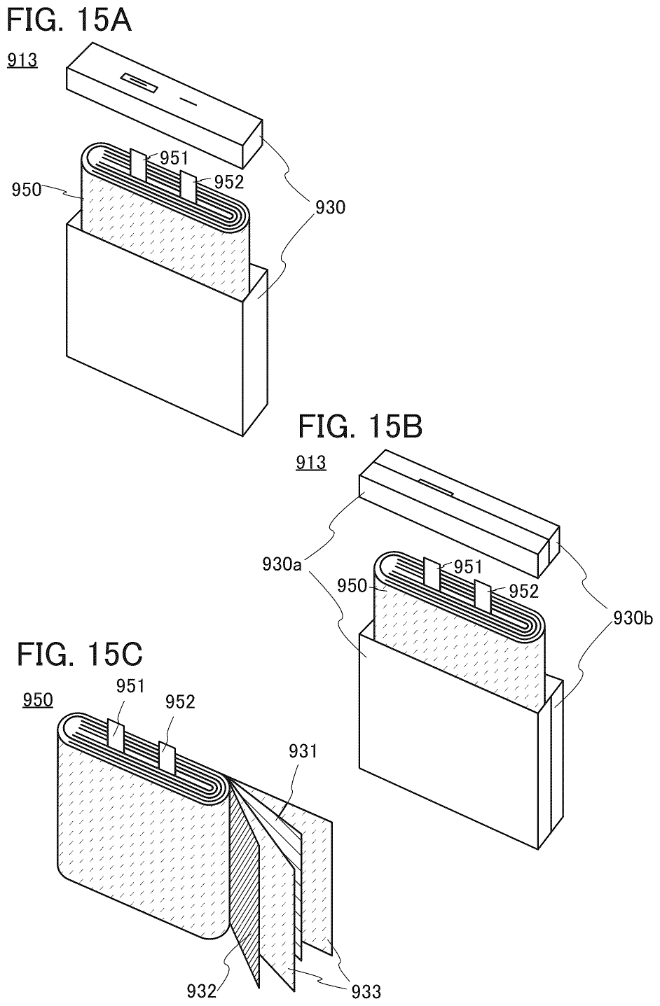

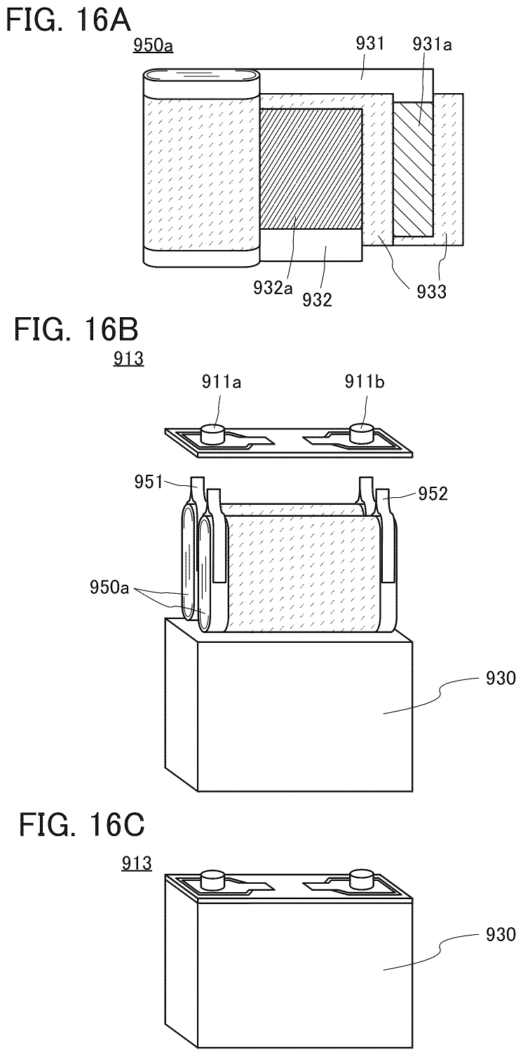

Structure examples of secondary batteries are described with reference to FIG. 15A to FIG. 16C.

A secondary battery 913 illustrated in FIG. 15A includes a wound body 950 provided with a terminal 951 and a terminal 952 inside a housing 930. The wound body 950 is immersed in an electrolyte solution inside the housing 930. The terminal 952 is in contact with the housing 930. The terminal 951 is not in contact with the housing 930 with use of an insulator or the like. Note that in FIG. 15A, the housing 930 divided into pieces is illustrated for convenience; however, in the actual structure, the wound body 950 is covered with the housing 930, and the terminal 951 and the terminal 952 extend to the outside of the housing 930. For the housing 930, a metal material (e.g., aluminum) or a resin material can be used.

Note that as illustrated in FIG. 15B, the housing 930 illustrated in FIG. 15A may be formed using a plurality of materials. For example, in the secondary battery 913 illustrated in FIG. 15B, a housing 930a and a housing 930b are attached to each other, and the wound body 950 is provided in a region surrounded by the housing 930a and the housing 930b.

For the housing 930a, an insulating material such as an organic resin can be used. In particular, when a material such as an organic resin is used for the side on which an antenna is formed, blocking of an electric field by the secondary battery 913 can be inhibited. When an electric field is not significantly blocked by the housing 930a, an antenna may be provided inside the housing 930a. For the housing 930b, a metal material can be used, for example.

FIG. 15C illustrates the structure of the wound body 950. The wound body 950 includes a negative electrode 931, a positive electrode 932, and separators 933. The wound body 950 is obtained by winding a sheet of a stack in which the negative electrode 931 and the positive electrode 932 overlap with each other with the separator 933 therebetween. Note that a plurality of stacks each including the negative electrode 931, the positive electrode 932, and the separators 933 may be further stacked.

As illustrated in FIG. 16, the secondary battery 913 may include a wound body 950a. The wound body 950a illustrated in FIG. 16A includes the negative electrode 931, the positive electrode 932, and the separators 933. The negative electrode 931 includes a negative electrode active material layer 931a. The positive electrode 932 includes a positive electrode active material layer 932a.

The separator 933 has a larger width than the negative electrode active material layer 931a and the positive electrode active material layer 932a, and is wound to overlap with the negative electrode active material layer 931a and the positive electrode active material layer 932a. In terms of safety, the width of the negative electrode active material layer 931a is preferably larger than that of the positive electrode active material layer 932a. The wound body 950a having such a shape is preferable because of its high level of safety and high productivity.

As illustrated in FIG. 16B, the negative electrode 931 is electrically connected to a terminal 951 by ultrasonic bonding, welding, or pressure bonding. The terminal 951 is electrically connected to a terminal 911a. The positive electrode 932 is electrically connected to a terminal 952 by ultrasonic bonding, welding, or pressure bonding. The terminal 952 is electrically connected to a terminal 911b.

As illustrated in FIG. 16C, the wound body 950a and an electrolyte solution are covered with the housing 930, whereby the secondary battery 913 is completed. The housing 930 is preferably provided with a safety valve, an overcurrent protection element, and the like. In order to prevent the battery from exploding, the safety valve is a valve to be released when the internal pressure of the housing 930 reaches a predetermined pressure.

As illustrated in FIG. 16B, the secondary battery 913 may include a plurality of the wound bodies 950a. The use of the plurality of wound bodies 950a enables the secondary battery 913 to have higher discharge capacity. The description of the secondary battery 913 illustrated in FIG. 15A to FIG. 15C can be referred to for the other components of the secondary battery 913 illustrated in FIG. 16A and FIG. 16B.

### <Laminated Secondary Battery>

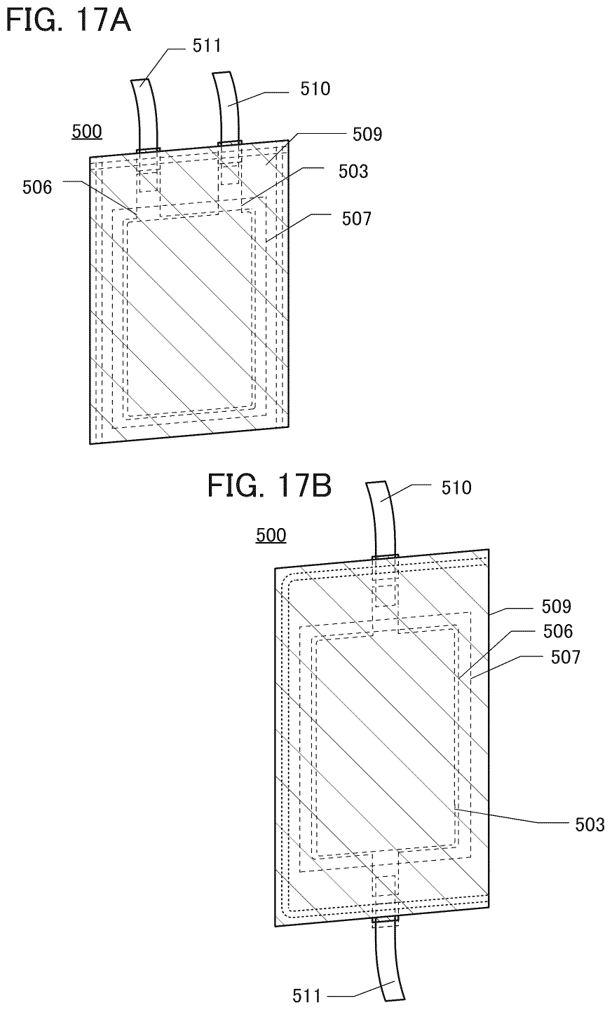

Next, examples of the appearance of a laminated secondary battery are illustrated in FIG. 17A and FIG. 17B. In FIG. 17A and FIG. 17B, a positive electrode 503, a negative electrode 506, a separator 507, an exterior body 509, a positive electrode lead electrode 510, and a negative electrode lead electrode 511 are included. A portion of the positive electrode lead electrode 510 that is exposed to the outside of the secondary battery can be referred to as a positive electrode terminal, and a portion of the negative electrode lead electrode 511 that is exposed to the outside of the secondary battery can be referred to as a negative electrode terminal.

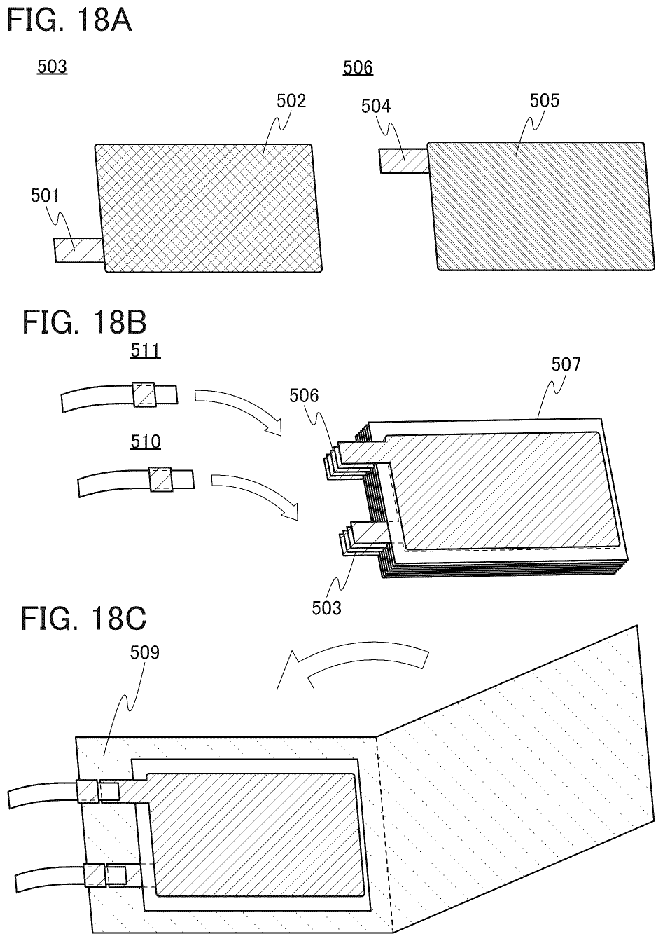

FIG. 18A illustrates the appearance of the positive electrode 503 and the negative electrode 506. The positive electrode 503 includes a positive electrode current collector 501, and a positive electrode active material layer 502 is formed on a surface of the positive electrode current collector 501. The positive electrode 503 also includes a region where the positive electrode current collector 501 is partly exposed (hereinafter referred to as a tab region). The negative electrode 506 includes a negative electrode current collector 504, and a negative electrode active material layer 505 is formed on a surface of the negative electrode current collector 504. The negative electrode 506 also includes a region where the negative electrode current collector 504 is partly exposed, that is, a tab region. The areas or the shapes of the tab regions included in the positive electrode and the negative electrode are not limited to the examples illustrated in FIG. 18A.

### <Method for Fabricating Laminated Secondary Battery>

An example of a method for fabricating the laminated secondary battery whose external view is illustrated in FIG. 17A will be described with reference to FIG. 18B and FIG. 18C.

First, the negative electrode 506, the separator 507, and the positive electrode 503 are stacked. FIG. 18B illustrates the negative electrodes 506, the separators 507, and the positive electrodes 503 that are stacked. Here, an example in which five negative electrodes and four positive electrodes are used is illustrated. The component can also be referred to as a stack including the negative electrodes, the separators, and the positive electrodes. Next, the tab regions of the positive electrodes 503 are bonded to each other, and the positive electrode lead electrode 510 is bonded to the tab region of the positive electrode on the outermost surface. The bonding is performed by ultrasonic welding, for example. In a similar manner, the tab regions of the negative electrodes 506 are bonded to each other, and the negative electrode lead electrode 511 is bonded to the tab region of the negative electrode on the outermost surface.

After that, the negative electrodes 506, the separators 507, and the positive electrodes 503 are placed over the exterior body 509.

Subsequently, the exterior body 509 is folded along a portion indicated by a dashed line, as illustrated in FIG. 18C. Then, the outer edges of the exterior body 509 are bonded to each other. The bonding is performed by thermocompression bonding, for example. At this time, an unbonded region (hereinafter referred to as an inlet) is provided for part (or one side) of the exterior body 509 so that an electrolyte solution can be introduced later.

Next, the electrolyte solution is introduced into the exterior body 509 from the inlet of the exterior body 509. The electrolyte solution is preferably introduced in a reduced pressure atmosphere or in an inert atmosphere. Lastly, the inlet is bonded. In this manner, the laminated secondary battery 500 can be fabricated.

### [Examples of Battery Pack]

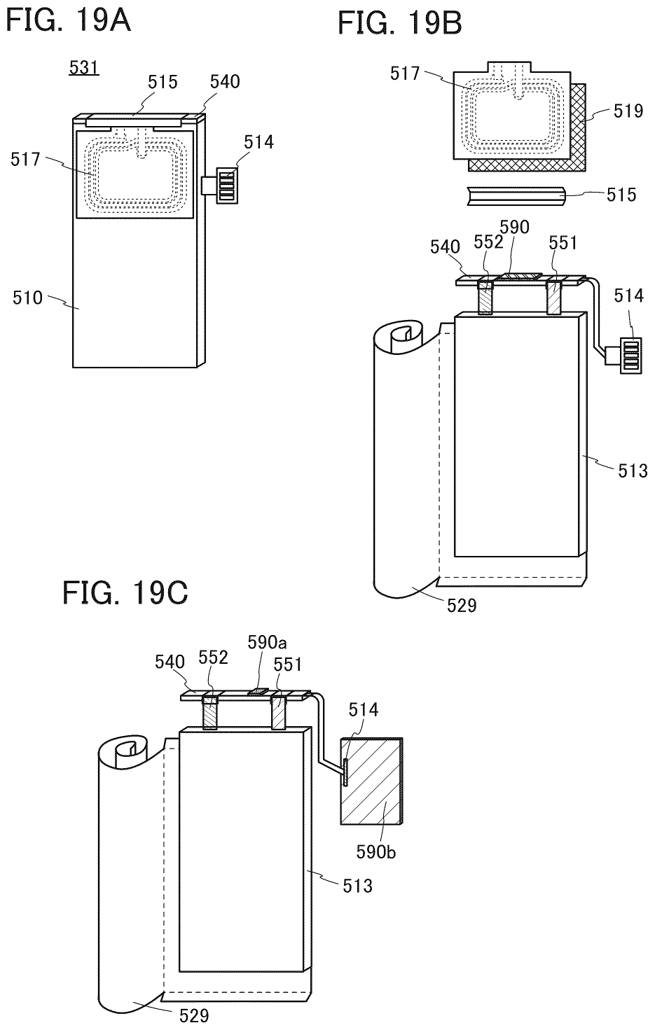

Examples of a secondary battery pack of one embodiment of the present invention that is capable of wireless charge using an antenna will be described with reference to FIG. 19.

FIG. 19A is a diagram illustrating the appearance of a secondary battery pack 531 that has a rectangular solid shape with a small thickness (also referred to as a flat plate shape with a certain thickness). FIG. 19B is a diagram illustrating a structure of the secondary battery pack 531. The secondary battery pack 531 includes a circuit board 540 and a secondary battery 513. A label 529 is attached to the secondary battery 513. The circuit board 540 is fixed by a sealant 515. The secondary battery pack 531 also includes an antenna 517.

A wound body or a stack may be included inside the secondary battery 513.

In the secondary battery pack 531, a control circuit 590 is provided over the circuit board 540 as illustrated in FIG. 19B, for example. The circuit board 540 is electrically connected to a terminal 514. The circuit board 540 is electrically connected to the antenna 517, one 551 of a positive electrode lead and a negative electrode lead of the secondary battery 513, and the other 552 of the positive electrode lead and the negative electrode lead. Note that in some cases, the positive electrode lead is referred to as a positive electrode terminal and the negative electrode lead is referred to as a negative electrode terminal.

In the secondary battery pack 531, the structure of the charge management system 100 or the like described in Embodiment 1 can be used for the structures of the secondary battery 513 and the control circuit 590.

Alternatively, as illustrated in FIG. 19C, a circuit system 590a provided over the circuit board 540 and a circuit system 590b electrically connected to the circuit board 540 through the terminal 514 may be included. Note that the terminal 514 includes a plurality of terminals including at least a high potential terminal (the external terminal 51 in FIG. 1B) and a low potential terminal (the external terminal 52 in FIG. 1B).

Note that the shape of the antenna 517 is not limited to a coil shape and may be a linear shape or a plate shape, for example. An antenna such as a planar antenna, an aperture antenna, a traveling-wave antenna, an EH antenna, a magnetic-field antenna, or a dielectric antenna may be used. Alternatively, the antenna 517 may be a flat-plate conductor. The flat-plate conductor can serve as one of conductors for electric field coupling. That is, the antenna 517 can function as one of two conductors of a capacitor. Thus, electric power can be transmitted and received not only by an electromagnetic field or a magnetic field but also by an electric field.

The secondary battery pack 531 includes a layer 519 between the antenna 517 and the secondary battery 513. The layer 519 has a function of blocking an electromagnetic field from the secondary battery 513, for example. As the layer 519, a magnetic material can be used, for example.

### Embodiment 4

In this embodiment, examples of vehicles each including the secondary battery of one embodiment of the present invention will be described. The structure of the charge management system 100 or the like described in Embodiment 1 can be used for the secondary battery and the control circuit described in this embodiment.

The secondary battery can be used in vehicles, typically automobiles. Examples of the automobiles include next-generation clean energy vehicles such as hybrid vehicles (HVs), electric vehicles (EVs), and plug-in hybrid vehicles (PHEVs or PHVs), and the secondary battery can be used as one of the power sources provided for the automobiles. The vehicles are not limited to automobiles. Examples of the vehicles include a train, a monorail train, a ship, a submarine (a deep-submergence vehicle and an unmanned submarine), a flying object (a helicopter, an unmanned aircraft (a drone), an airplane, a rocket, and an artificial satellite), an electric bicycle, and an electric motorcycle, and the secondary battery of one embodiment of the present invention can be used for the vehicles.

The electric vehicle is provided with first power storage devices 1301a and 1301b as main secondary batteries for driving and a second power storage device 1311 that supplies electric power to an inverter 1312 for starting a motor 1304. The second power storage device 1311 is also referred to as a cranking battery (also referred to as a starter battery). The second power storage device 1311 only needs high output and high capacity is not so much needed; the capacity of the second power storage device 1311 is lower than that of the first power storage devices 1301a and 1301b.

The internal structure of the first power storage device 1301a may be the wound structure illustrated in FIG. 15C or FIG. 16A or the stacked-layer structure illustrated in FIG. 17A or FIG. 17B. Alternatively, the all-solid-state battery may be used as the first power storage device 1301a. The use of the all-solid-state battery as the first power storage device 1301a can achieve high capacity, improvement in safety, and reduction in size and weight.

Although this embodiment describes an example in which the two first power storage devices 1301a and 1301b are connected in parallel, three or more power storage devices may be connected in parallel. In the case where the first power storage device 1301a can store sufficient electric power, the first power storage device 1301b may be omitted. A battery pack including a plurality of secondary batteries is formed using the power storage device, whereby large electric power can be extracted. The plurality of secondary batteries may be connected in parallel, connected in series, or connected in series after being connected in parallel. The plurality of secondary batteries are also referred collectively to as an assembled battery.

In order to cut off electric power from the plurality of secondary batteries, the secondary batteries in the vehicle include a service plug or a circuit breaker that can cut off a high voltage without the use of equipment. The first power storage device 1301a is provided with such a service plug or a circuit breaker.

Electric power from the first power storage devices 1301a and 1301b is mainly used to rotate the motor 1304 and is supplied to in-vehicle parts for 42 V (such as an electric power steering 1307, a heater 1308, and a defogger 1309) through a DCDC circuit 1306. Even in the case where there is a rear motor 1317 for rear wheels, the first power storage device 1301a is used to rotate the rear motor 1317.

The second power storage device 1311 supplies electric power to in-vehicle parts for 14 V (such as a stereo 1313, a power window 1314, and lamps 1315) through a DCDC circuit 1310.

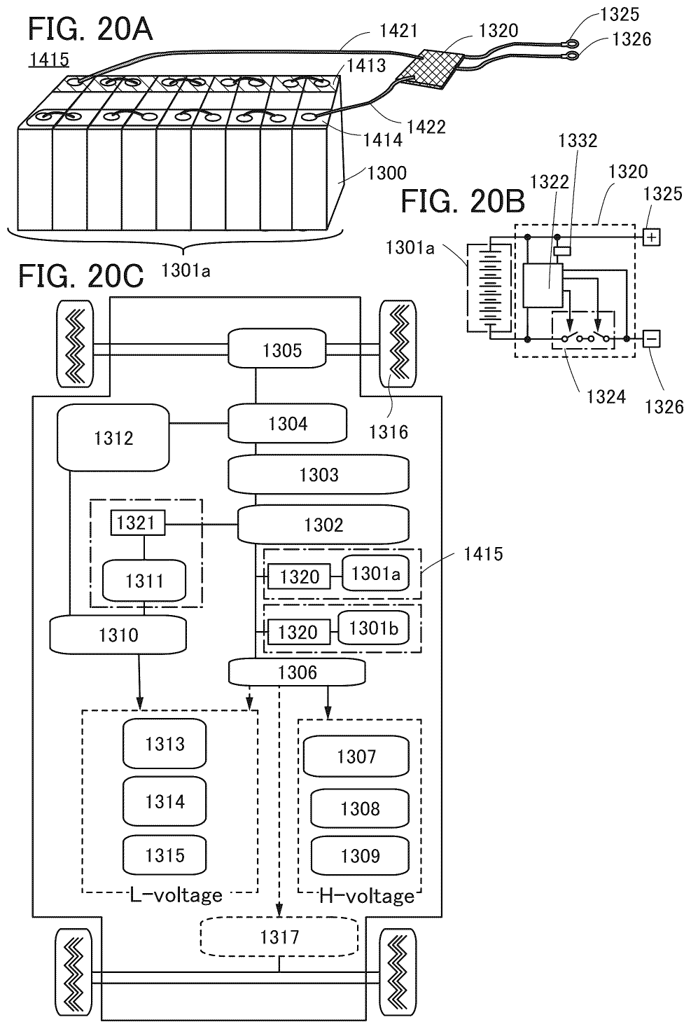

Next, the first power storage device 1301a is described with reference to FIG. 20A.

FIG. 20A illustrates an example in which nine rectangular secondary batteries 1300 form one power storage module 1415. The nine rectangular secondary batteries 1300 are connected in series; one electrode of each battery is fixed by a fixing portion 1413 made of an insulator, and the other electrode thereof is fixed by a fixing portion 1414 made of an insulator. Although this embodiment describes an example in which the secondary batteries are fixed by the fixing portions 1413 and 1414, they may be stored in a battery container box (also referred to as a housing). Since a vibration or a jolt is assumed to be given to the vehicle from the outside (e.g., a road surface), the plurality of secondary batteries are preferably fixed by the fixing portion 1413 or 1414, a battery container box, or the like. Furthermore, the one electrode is electrically connected to a control circuit portion 1320 through a wiring 1421. Furthermore, the other electrode is electrically connected to the control circuit portion 1320 through a wiring 1422. In the first power storage device 1301a, between the electrodes connected to the wiring 1421 and the electrodes connected to the wiring 1422, the electrodes with high potentials can be referred to as a positive electrode terminal of the first power storage device 1301a, and the electrodes with low potentials can be referred to as a negative electrode terminal of the first power storage device 1301a. The control circuit portion 1320 includes an external connection terminal 1325 and an external connection terminal 1326.

The control circuit portion 1320 may include a memory circuit including a transistor using an oxide semiconductor. A charge control circuit or a battery control system that includes a memory circuit including a transistor using an oxide semiconductor is referred to as a BTOS (Battery operating system or Battery oxide semiconductor) in some cases.

A metal oxide functioning as an oxide semiconductor is preferably used. For example, as the metal oxide, a metal oxide such as an In-M-Zn oxide (an element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) or the like is preferably used. In particular, the In-M-Zn oxide that can be used as the metal oxide is preferably a CAAC-OS (C-Axis Aligned Crystal Oxide Semiconductor) or a CAC-OS (Cloud-Aligned Composite Oxide Semiconductor). Alternatively, an In—Ga oxide or an In—Zn oxide may be used as the metal oxide. The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement.

Note that the “CAC-OS” has a composition in which materials are separated into first regions and second regions to form a mosaic pattern, and the first regions are distributed in the film (this composition is hereinafter also referred to as a cloud-like composition). That is, the CAC-OS is a composite metal oxide having a composition in which the first regions and the second regions are mixed. Note that a clear boundary between the first region and the second region is not easily observed in some cases.

For example, energy dispersive X-ray spectroscopy (EDX) is used to obtain EDX mapping, and according to the EDX mapping, the CAC-OS in the In—Ga—Zn oxide can be found to have a structure in which the region containing In as its main component (the first region) and the region containing Ga as its main component (the second region) are unevenly distributed and mixed.

In the case where the CAC-OS is used for a transistor, a switching function (On/Off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (μ), and favorable switching operation can be achieved.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

The control circuit portion 1320 preferably includes a transistor using an oxide semiconductor because it can be used in a high-temperature environment. For the process simplicity, the control circuit portion 1320 may be formed using transistors of the same conductivity type. A transistor using an oxide semiconductor in its semiconductor layer has an operating ambient temperature range of −40° C. to 150° C., which is wider than that of a single crystal Si transistor, and thus shows a smaller change in characteristics than the single crystal Si transistor when the secondary battery is overheated. The off-state current of the transistor using an oxide semiconductor is lower than or equal to the lower measurement limit even at 150° C. independently of the temperature; meanwhile, the off-state current characteristics of the single crystal Si transistor largely depend on the temperature. For example, at 150° C., the off-state current of the single crystal Si transistor increases, and a sufficiently high current on/off ratio cannot be obtained. The control circuit portion 1320 can improve the safety.

The control circuit portion 1320 that includes a memory circuit including a transistor using an oxide semiconductor can also function as an automatic control device for the secondary battery to resolve causes of instability, such as a micro-short circuit. Examples of functions of resolving causes of instability such as a micro-short circuit include prevention of overcharge, prevention of overcurrent, control of overheating during charge, cell balance of an assembled battery, prevention of overdischarge, a battery indicator, automatic control of charge voltage and current amount according to temperature, control of the amount of charge current according to the degree of deterioration, abnormal behavior sensing for a micro-short circuit, and anomaly prediction regarding a micro-short circuit; the control circuit portion 1320 has at least one of these functions. Furthermore, the automatic control device for the secondary battery can be extremely small in size.

A “micro-short circuit” refers to a minute short circuit caused in a secondary battery and refers not to a state where the positive electrode and the negative electrode of a secondary battery are short-circuited so that charge and discharge are impossible, but to a phenomenon in which a slight short-circuit current flows through a minute short-circuit portion. Since a large voltage change is caused even when a micro-short circuit occurs in a relatively short time in a minute area, the abnormal voltage value might adversely affect estimation to be performed subsequently.

One of the causes of a micro-short circuit is as follows: charge and discharge performed a plurality of times cause uneven distribution of positive electrode active materials, which leads to local concentration of current in part of the positive electrode and part of the negative electrode, whereby part of a separator stops functioning or a by-product is generated by a side reaction, which is thought to generate a micro short-circuit.

It can be said that the control circuit portion 1320 not only senses a micro-short circuit but also senses a terminal voltage of the secondary battery and controls the charge and discharge state of the secondary battery. For example, to prevent overcharge, an output transistor of a charge circuit and an interruption switch can be turned off substantially at the same time.

Next, FIG. 20B illustrates an example of a block diagram of the power storage module 1415 illustrated in FIG. 20A.

The control circuit portion 1320 includes a switch portion 1324 that includes at least a switch for preventing overcharge and a switch for preventing overdischarge, a control circuit 1322 for controlling the switch portion 1324, a portion for measuring the voltage of the first power storage device 1301a, and a PTC element 1332. The control circuit portion 1320 is set to have the upper limit voltage and the lower limit voltage of the secondary battery to be used, and imposes the upper limit of current from the outside, the upper limit of output current to the outside, or the like. The range from the lower limit voltage to the upper limit voltage of the secondary battery falls within the recommended voltage range; when a voltage falls outside the range, the switch portion 1324 operates and functions as a protection circuit. The control circuit portion 1320 can also be referred to as a protection circuit because it controls the switch portion 1324 to prevent overdischarge and/or overcharge. For example, when the control circuit 1322 senses a voltage that is likely to cause overcharge, current is interrupted by turning off the switch in the switch portion 1324. Furthermore, a function of interrupting current in accordance with a temperature rise may be set by providing a PTC element in the charge and discharge path. The control circuit portion 1320 includes the external connection terminal 1325 (+IN) and the external connection terminal 1326 (−IN).

The switch portion 1324 can be formed by a combination of an n-channel transistor and a p-channel transistor. The switch portion 1324 is not limited to a switch including a Si transistor using single crystal silicon; the switch portion 1324 may be formed using, for example, a power transistor containing Ge (germanium), SiGe (silicon germanium), GaAs (gallium arsenide), GaAlAs (gallium aluminum arsenide), InP (indium phosphide), SiC (silicon carbide), ZnSe (zinc selenide), GaN (gallium nitride), GaOx (gallium oxide, where x is a real number greater than 0), or the like. A memory element using an OS transistor can be freely placed by being stacked over a circuit using a Si transistor, for example; hence, integration can be easy. Furthermore, an OS transistor can be fabricated with a manufacturing apparatus similar to that for a Si transistor and thus can be fabricated at low cost. That is, the control circuit portion 1320 using an OS transistor can be stacked over the switch portion 1324 so that they can be integrated into one chip. Since the volume occupied by the control circuit portion 1320 can be reduced, a reduction in size is possible.

Next, FIG. 20C illustrates an example of a block diagram of a vehicle including the power storage module 1415 illustrated in FIG. 20A.

The first power storage devices 1301a and 1301b mainly supply electric power to in-vehicle parts for 42 V (high-voltage systems), and the second power storage device 1311 supplies electric power to in-vehicle parts for 14 V (low-voltage systems). Lead storage batteries are usually used for the second power storage device 1311 due to cost advantage. Lead storage batteries have disadvantages compared with lithium-ion batteries in that they have a larger amount of self-discharge and are more likely to deteriorate due to a phenomenon called sulfation. There is an advantage that the second power storage device 1311 can be maintenance-free when a lithium-ion battery is used; however, in the case of long-term use, for example three years or more, anomaly that is difficult to determine at the time of manufacturing might occur. In particular, when the second power storage device 1311 that starts the inverter becomes inoperative, the motor cannot be started even when the first power storage devices 1301a and 1301b have remaining capacity; thus, in order to prevent this, in the case where the second power storage device 1311 is a lead storage battery, the second battery is supplied with electric power from the first battery to constantly maintain a fully-charged state.

In this embodiment, an example in which a lithium-ion battery is used as both the first power storage device 1301a and the second power storage device 1311 is described. As the second power storage device 1311, a lead storage battery, an all-solid-state battery, or an electric double layer capacitor may be used. For example, the all-solid-state battery may be used. The use of the all-solid-state battery as the second power storage device 1311 can achieve high capacity and reduction in size and weight.

Regenerative energy generated by rolling of tires 1316 is transmitted to the motor 1304 through a gear 1305, and is stored in the second power storage device 1311 from a motor controller 1303 and a battery controller 1302 through a control circuit portion 1321. Alternatively, the regenerative energy is stored in the first power storage device 1301a from the battery controller 1302 through the control circuit portion 1320. Alternatively, the regenerative energy is stored in the first power storage device 1301b from the battery controller 1302 through the control circuit portion 1320. For efficient charge with regenerative energy, the first power storage devices 1301a and 1301b are desirably capable of fast charge.

The battery controller 1302 can set the charge voltage, charge current, and the like of the first power storage devices 1301a and 1301b. The battery controller 1302 can set charge conditions in accordance with charge performance of a secondary battery used, so that fast charge can be performed.

Although not illustrated, in the case of being connected to an external charger, the battery controller 1302 is electrically connected to a plug of the charger or a connection cable of the charger. Electric power supplied from the external charger is stored in the first power storage devices 1301a and 1301b through the battery controller 1302. Some chargers are provided with a control circuit, in which case the function of the battery controller 1302 is not used; to prevent overcharge, the first power storage devices 1301a and 1301b are preferably charged through the control circuit portion 1320. In addition, the connection cable or the connection cable of the charger is sometimes provided with a control circuit. The control circuit portion 1320 is also referred to as an ECU (Electronic Control Unit). The ECU is connected to a CAN (Controller Area Network) provided in the electric motor vehicle. The CAN is a type of a serial communication standard used as an in-vehicle LAN. The ECU includes a microcomputer. Moreover, the ECU uses a CPU or a GPU.

External chargers installed at charging stations and the like have a 100 V outlet, a 200 V outlet, or a three-phase 200 V outlet with 50 kW, for example. Furthermore, charge can be performed with electric power supplied from external charging equipment by a contactless power feeding method or the like.

For fast charge, secondary batteries that can withstand high-voltage charge have been desired to perform charge in a short time.

Moreover, it is possible to achieve a secondary battery in which graphene is used as a conductive material, an electrode layer is formed thick to increase the loading amount while suppressing a reduction in capacity, and the electrical characteristics are significantly improved in synergy with maintenance of high capacity. This secondary battery is particularly effectively used in a vehicle; it is possible to provide a vehicle that has a long cruising range, specifically one charge mileage of 500 km or greater, without increasing the proportion of the weight of the secondary battery to the weight of the entire vehicle.

Next, examples in which the secondary battery of one embodiment of the present invention is mounted on a vehicle, typically a transport vehicle, will be described.

Mounting the secondary battery illustrated in any of FIG. 14D, FIG. 16C, and FIG. 20A on vehicles can achieve next-generation clean energy vehicles such as hybrid vehicles (HVs), electric vehicles (EVs), and plug-in hybrid vehicles (PHVs). The secondary battery can also be mounted on agricultural machines, motorized bicycles including motor-assisted bicycles, motorcycles, electric wheelchairs, electric carts, boats and ships, submarines, aircraft, rockets, artificial satellites, space probes, planetary probes, or spacecraft. The secondary battery of one embodiment of the present invention can be a secondary battery with high capacity. Thus, the secondary battery of one embodiment of the present invention is suitable for reduction in size and reduction in weight and is preferably used in transport vehicles.

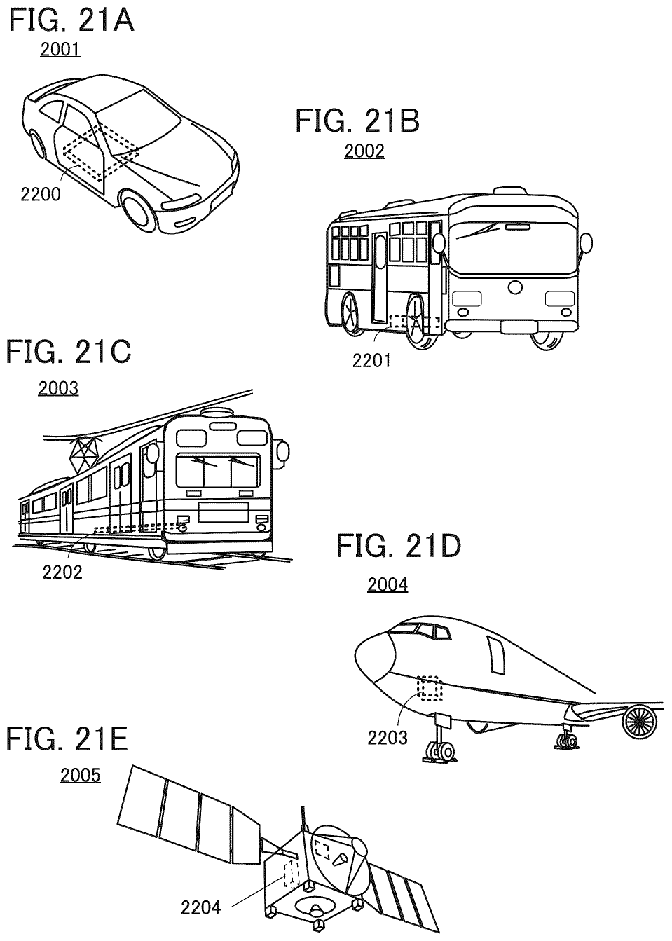

FIG. 21A to FIG. 21D illustrate examples of transport vehicles using one embodiment of the present invention. An automobile 2001 illustrated in FIG. 21A is an electric vehicle that runs using an electric motor as a driving power source. Alternatively, the automobile 2001 is a hybrid vehicle that enables appropriate selection of an electric motor or an engine as a driving power source. In the case where the secondary battery is mounted on the vehicle, an example of the secondary battery described in Embodiment 3 is provided at one position or several positions. The automobile 2001 illustrated in FIG. 21A includes a battery pack 2200, and the battery pack includes a power storage module in which a plurality of secondary batteries are connected to each other. Moreover, the battery pack preferably includes a charge control device that is electrically connected to the power storage module.

The automobile 2001 can be charged when the secondary battery included in the automobile 2001 is supplied with electric power from external charge equipment by a plug-in system, a contactless charge system, or the like. In charge, a given method such as CHAdeMO (registered trademark) or Combined Charging System may be employed as a charge method, the standard of a connector, or the like as appropriate. A charging battery may be a charging station provided in a commerce facility or a household power supply. For example, with the use of a plug-in technique, the power storage device mounted on the automobile 2001 can be charged by being supplied with electric power from the outside. Charge can be performed by converting AC power into DC power through a converter such as an ACDC converter.

Although not illustrated, the vehicle may be provided with a power receiving device so that it can be charged by being supplied with electric power from an above-ground power transmitting device in a contactless manner. In the case of the contactless power feeding system, by fitting a power transmitting device in a road or an exterior wall, charge can be performed not only when the vehicle is stopped but also when moving. In addition, the contactless power feeding system may be utilized to perform transmission and reception of electric power between two vehicles. Furthermore, a solar cell may be provided in the exterior of the vehicle to charge the secondary battery while the vehicle is stopped or while the vehicle is moving. To supply electric power in such a contactless manner, an electromagnetic induction method or a magnetic resonance method can be used.

FIG. 21B illustrates a large transporter 2002 having a motor controlled by electricity, as an example of a transport vehicle. In a power storage module of the transporter 2002, four secondary batteries each having a nominal voltage of 3.0 V or higher and 5.0 V or lower are used as a cell unit, and 48 cells are connected in series to have a maximum voltage of 170 V, for example. A battery pack 2201 has the same function as that in FIG. 21A except, for example, the number of secondary batteries configuring the power storage module; thus, the description is omitted.

FIG. 21C illustrates a large transport vehicle 2003 having a motor controlled by electricity as an example. In a power storage module of the transport vehicle 2003, 100 or more secondary batteries each having a nominal voltage of 3.0 V or higher and 5.0 V or lower are connected in series to have a maximum voltage of 600 V, for example. Thus, the secondary batteries are required to have a small variation in the characteristics.

FIG. 21D illustrates an aircraft 2004 having a combustion engine as an example. The aircraft 2004 illustrated in FIG. 21D can also be regarded as a kind of transport vehicle because it has wheels for takeoff and landing, and includes a battery pack 2203 that includes a charge control device and a power storage module configured by connecting a plurality of secondary batteries.

The power storage module of the aircraft 2004 has eight 4 V secondary batteries connected in series, which has a maximum voltage of 32 V, for example. The battery pack 2203 has the same function as that in FIG. 21A except, for example, the number of secondary batteries configuring the power storage module; thus, the description is omitted.

FIG. 21E illustrates an artificial satellite 2005 including a secondary battery 2204 as an example. Because the artificial satellite 2005 is used in an ultra-low-temperature cosmic space, the secondary battery 2204 having excellent low temperature resistance of one embodiment of the present invention is preferably provided. It is further preferable that the secondary battery 2204 be mounted inside the artificial satellite 2005 while being covered with a heat-retaining member.

### Embodiment 5

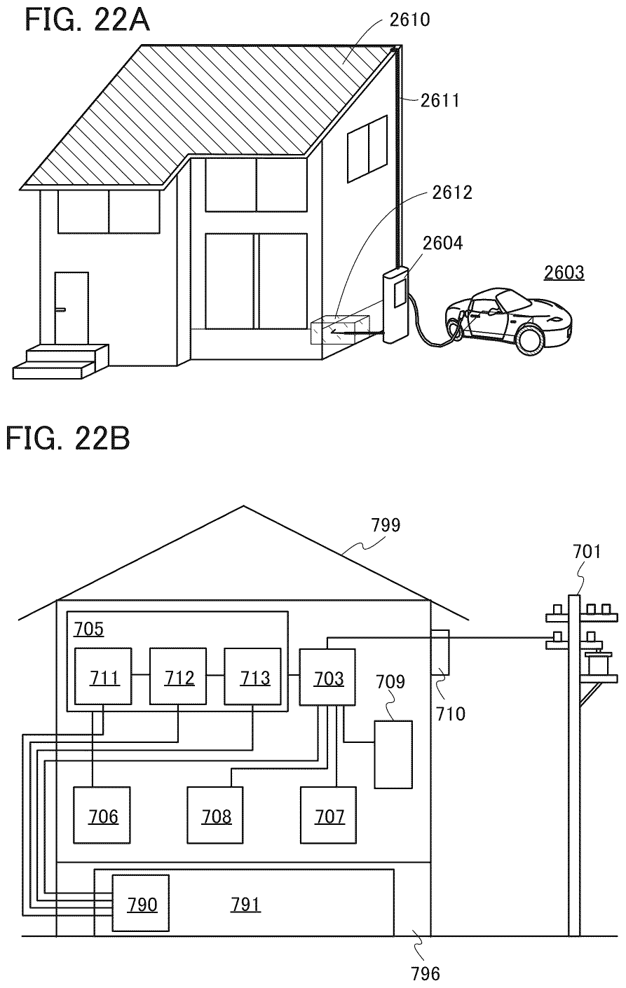

In this embodiment, examples in which the secondary battery of one embodiment of the present invention is mounted on a building will be described with reference to FIG. 22A and FIG. 22B. The structure of the charge management system 100 or the like described in Embodiment 1 can be used for the secondary battery and the control circuit described in this embodiment.

A house illustrated in FIG. 22A includes a power storage device 2612 including the secondary battery of one embodiment of the present invention and a solar panel 2610. The power storage device 2612 is electrically connected to the solar panel 2610 through a wiring 2611 or the like. The power storage device 2612 may be electrically connected to a ground-based charge apparatus 2604. The power storage device 2612 can be charged with electric power generated by the solar panel 2610. A secondary battery included in a vehicle 2603 can be charged with the electric power stored in the power storage device 2612 through the charge apparatus 2604. The power storage device 2612 is preferably provided in an underfloor space. When the power storage device 2612 is provided in the underfloor space, the space on the floor can be effectively used. Alternatively, the power storage device 2612 may be provided on the floor.

The electric power stored in the power storage device 2612 can also be supplied to other electronic devices in the house. Thus, with use of the power storage device 2612 of one embodiment of the present invention as an uninterruptible power source, electronic devices can be used even when electric power cannot be supplied from a commercial power source due to power failure or the like.

FIG. 22B illustrates an example of a power storage device of one embodiment of the present invention. As illustrated in FIG. 22B, a power storage device 791 of one embodiment of the present invention is provided in an underfloor space 796 of a building 799.

The power storage device 791 is provided with a control device 790, and the control device 790 is electrically connected to a distribution board 703, a power storage controller 705 (also referred to as a control device), an indicator 706, and a router 709 through wirings.

Electric power is transmitted from a commercial power source 701 to the distribution board 703 through a service wire mounting portion 710. Moreover, electric power is transmitted to the distribution board 703 from the power storage device 791 and the commercial power source 701, and the distribution board 703 supplies the transmitted electric power to a general load 707 and a power storage load 708 through outlets (not illustrated).

The general load 707 is, for example, an electronic device such as a TV or a personal computer. The power storage load 708 is, for example, an electronic device such as a microwave oven, a refrigerator, or an air conditioner.

The power storage controller 705 includes a measuring portion 711, a predicting portion 712, and a planning portion 713. The measuring portion 711 has a function of measuring the amount of electric power consumed by the general load 707 and the power storage load 708 during a day (e.g., from midnight to midnight). The measuring portion 711 may have a function of measuring the amount of electric power of the power storage device 791 and the amount of electric power supplied from the commercial power source 701. The predicting portion 712 has a function of predicting, on the basis of the amount of electric power consumed by the general load 707 and the power storage load 708 during a given day, the demand for electric power consumed by the general load 707 and the power storage load 708 during the next day. The planning portion 713 has a function of making a charge and discharge plan of the power storage device 791 on the basis of the demand for electric power predicted by the predicting portion 712.

The amount of electric power consumed by the general load 707 and the power storage load 708 and measured by the measuring portion 711 can be checked with the indicator 706. It can also be checked with an electronic device such as a TV or a personal computer through the router 709. Furthermore, it can be checked with a portable electronic terminal such as a smartphone or a tablet through the router 709. With the indicator 706, the electronic device, or the portable electronic terminal, the demand for electric power in every time period (or per hour) that is predicted by the predicting portion 712 can be checked.

### Embodiment 6

This embodiment describes examples in which the lithium-ion battery of one embodiment of the present invention is mounted on a two-wheeled vehicle and a bicycle as examples of mounting a secondary battery on a vehicle. The structure of the charge management system 100 or the like described in Embodiment 1 can be used for the secondary battery and the control circuit described in this embodiment.

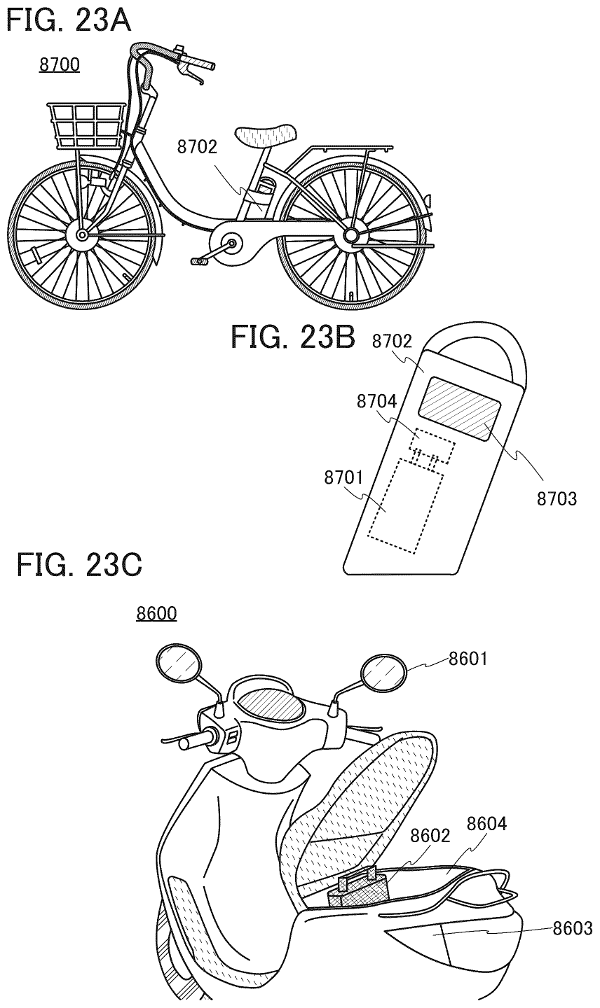

FIG. 23A illustrates an example of an electric bicycle using the power storage device of one embodiment of the present invention. The power storage device of one embodiment of the present invention can be used for an electric bicycle 8700 illustrated in FIG. 23A. The power storage device of one embodiment of the present invention includes a plurality of storage batteries and a protection circuit, for example.

The electric bicycle 8700 includes a power storage device 8702. The power storage device 8702 can supply electricity to a motor that assists a rider. The power storage device 8702 is portable, and FIG. 23B illustrates the state where the power storage device 8702 is detached from the bicycle. A plurality of storage batteries 8701 included in the power storage device of one embodiment of the present invention are incorporated in the power storage device 8702, and the remaining battery capacity and the like can be displayed on a display portion 8703. The power storage device 8702 includes a control circuit 8704 capable of charge control or anomaly sensing for the secondary battery, which is exemplified in Embodiment 6. The control circuit 8704 is electrically connected to a positive electrode and a negative electrode of the storage battery 8701.

FIG. 23C illustrates an example of a two-wheeled vehicle including the power storage device of one embodiment of the present invention. A motor scooter 8600 illustrated in FIG. 23C includes a power storage device 8602, side mirrors 8601, and indicator lights 8603. The power storage device 8602 can supply electricity to the indicator lights 8603.

In the motor scooter 8600 illustrated in FIG. 23C, the power storage device 8602 can be stored in an under-seat storage unit 8604. The power storage device 8602 can be stored in the under-seat storage unit 8604 even when the under-seat storage unit 8604 is small.

### Embodiment 7

In this embodiment, examples of electronic devices each including the secondary battery of one embodiment of the present invention will be described. Examples of electronic devices including the secondary battery include a television device (also referred to as a television or a television receiver), a monitor of a computer and the like, a digital camera, a digital video camera, a digital photo frame, a mobile phone (also referred to as a cellular phone or a mobile phone device), a portable game machine, a portable information terminal, an audio reproducing device, and a large-sized game machine such as a pachinko machine. Examples of the portable information terminal include a laptop personal computer, a tablet terminal, an e-book reader, and a mobile phone. The structure of the charge management system 100 or the like described in Embodiment 1 can be used for the secondary battery and the control circuit described in this embodiment.

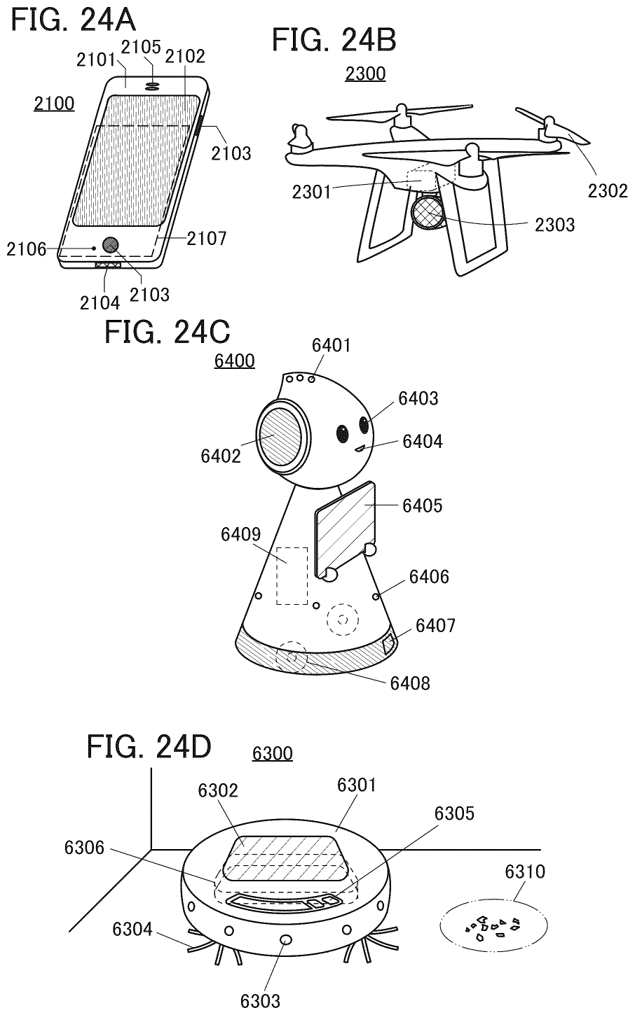

FIG. 24A illustrates an example of a mobile phone. A mobile phone 2100 includes a display portion 2102 set in a housing 2101, operation buttons 2103, an external connection port 2104, a speaker 2105, a microphone 2106, and the like. The mobile phone 2100 includes a secondary battery 2107.

The mobile phone 2100 is capable of executing a variety of applications such as mobile phone calls, e-mailing, text viewing and editing, music reproduction, Internet communication, and a computer game.

With the operation buttons 2103, a variety of functions such as time setting, power on/off, on/off of wireless communication, setting and cancellation of a silent mode, and setting and cancellation of a power saving mode can be performed. For example, the functions of the operation buttons 2103 can be set freely by an operating system incorporated in the mobile phone 2100.

The mobile phone 2100 can execute near field communication conformable to a communication standard. For example, mutual communication between the mobile phone 2100 and a headset capable of wireless communication enables hands-free calling.

The mobile phone 2100 includes the external connection port 2104, and can perform direct data transmission and reception with another information terminal via a connector. In addition, charge can be performed via the external connection port 2104. Note that the charging operation may be performed by wireless power feeding without using the external connection port 2104.

The mobile phone 2100 preferably includes a sensor. As the sensor, a human body sensor such as a fingerprint sensor, a pulse sensor, or a temperature sensor, a touch sensor, a pressure sensitive sensor, or an acceleration sensor is preferably mounted, for example.

FIG. 24B illustrates an unmanned aircraft 2300 including a plurality of rotors 2302. The unmanned aircraft 2300 is sometimes also referred to as a drone. The unmanned aircraft 2300 includes a secondary battery 2301 of one embodiment of the present invention, a camera 2303, and an antenna (not illustrated). The unmanned aircraft 2300 can be remotely controlled through the antenna.

FIG. 24C illustrates an example of a robot. A robot 6400 illustrated in FIG. 24C includes a secondary battery 6409, an illuminance sensor 6401, a microphone 6402, an upper camera 6403, a speaker 6404, a display portion 6405, a lower camera 6406, an obstacle sensor 6407, a moving mechanism 6408, an arithmetic device, and the like.

The microphone 6402 has a function of sensing a speaking voice of a user, an environmental sound, and the like. The speaker 6404 has a function of outputting sound. The robot 6400 can communicate with the user using the microphone 6402 and the speaker 6404.

The display portion 6405 has a function of displaying various kinds of information. The robot 6400 can display information desired by the user on the display portion 6405. The display portion 6405 may be provided with a touch panel. Moreover, the display portion 6405 may be a detachable information terminal, in which case charge and data communication can be performed when the display portion 6405 is set at the home position of the robot 6400.

The upper camera 6403 and the lower camera 6406 each have a function of taking an image of the surroundings of the robot 6400. The obstacle sensor 6407 can sense the presence of an obstacle in the direction where the robot 6400 advances with the moving mechanism 6408. The robot 6400 can move safely by recognizing the surroundings with the upper camera 6403, the lower camera 6406, and the obstacle sensor 6407.

The robot 6400 includes, in its inner region, the secondary battery 6409 of one embodiment of the present invention and a semiconductor device or an electronic component.

FIG. 24D illustrates an example of a cleaning robot. A cleaning robot 6300 includes a display portion 6302 placed on a top surface of a housing 6301, a plurality of cameras 6303 placed on a side surface of the housing 6301, a brush 6304, operation buttons 6305, a secondary battery 6306, a variety of sensors, and the like. Although not illustrated, the cleaning robot 6300 is provided with a tire, an inlet, and the like. The cleaning robot 6300 is self-propelled, senses dust 6310, and sucks up the dust through the inlet provided on a bottom surface.

The cleaning robot 6300 can determine whether there is an obstacle such as a wall, furniture, or a step by analyzing images taken by the cameras 6303. In the case where the cleaning robot 6300 senses an object, such as a wire, that is likely to be caught in the brush 6304 by image analysis, the rotation of the brush 6304 can be stopped. The cleaning robot 6300 includes, in its inner region, the secondary battery 6306 according to one embodiment of the present invention and a semiconductor device or an electronic component.

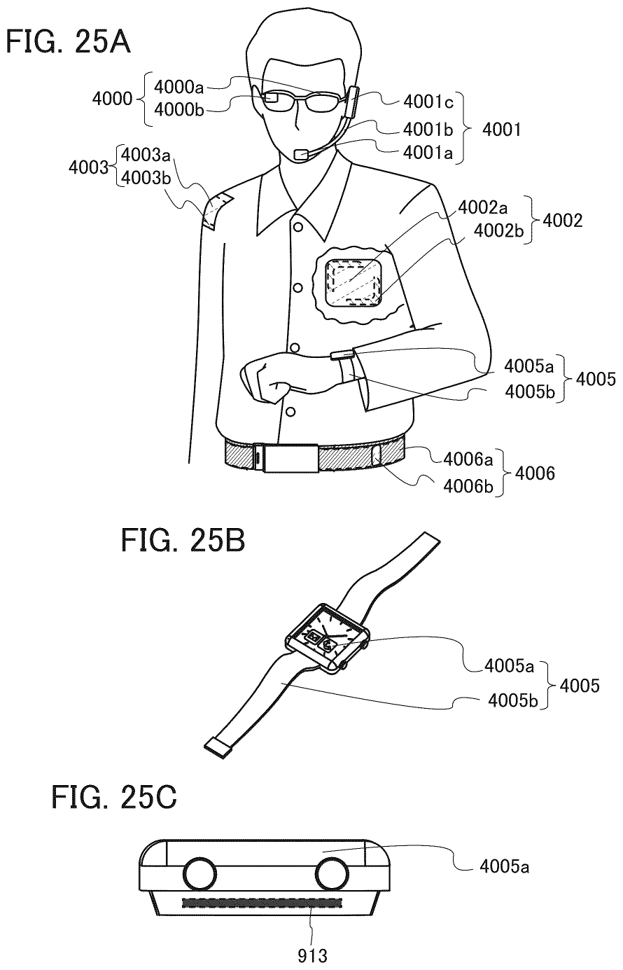

FIG. 25A illustrates examples of wearable devices. A secondary battery is used as a power source of a wearable device. To have improved splash resistance, water resistance, or dust resistance in daily use or outdoor use by a user, a wearable device is desirably capable of being charged with and without a wire whose connector portion for connection is exposed.

For example, the secondary battery of one embodiment of the present invention can be mounted in a glasses-type device 4000 illustrated in FIG. 25A. The glasses-type device 4000 includes a frame 4000a and a display portion 4000b. The secondary battery is mounted in a temple portion of the frame 4000a having a curved shape, whereby the glasses-type device 4000 can be lightweight, can have a well-balanced weight, and can be used continuously for a long time.

The secondary battery of one embodiment of the present invention can be mounted in a headset-type device 4001. The headset-type device 4001 includes at least a microphone portion 4001a, a flexible pipe 4001b, and an earphone portion 4001c. The secondary battery can be provided in the flexible pipe 4001b or the earphone portion 4001c.

The secondary battery of one embodiment of the present invention can be mounted in a device 4002 that can be attached directly to a body. A secondary battery 4002b can be provided in a thin housing 4002a of the device 4002.

The secondary battery of one embodiment of the present invention can be mounted in a device 4003 that can be attached to clothes. A secondary battery 4003b can be provided in a thin housing 4003a of the device 4003.

The secondary battery of one embodiment of the present invention can be mounted in a belt-type device 4006. The belt-type device 4006 includes a belt portion 4006a and a wireless power feeding and receiving portion 4006b, and the secondary battery can be mounted in the inner region of the belt portion 4006a.

The secondary battery of one embodiment of the present invention can be mounted in a watch-type device 4005. The watch-type device 4005 includes a display portion 4005a and a belt portion 4005b, and the secondary battery can be provided in the display portion 4005a or the belt portion 4005b.

The display portion 4005a can display various kinds of information such as time and reception information of an e-mail and an incoming call.

The watch-type device 4005 is a wearable device that is wound around an arm directly; thus, a sensor that measures the pulse, the blood pressure, or the like of the user may be mounted therein. Data on the exercise quantity and health of the user can be stored to be used for health maintenance.

FIG. 25B illustrates a perspective view of the watch-type device 4005 that is detached from an arm.

FIG. 25C illustrates a side view. FIG. 25C illustrates a state where a secondary battery 913 is incorporated in the inner region. The secondary battery 913 is the secondary battery described in Embodiment 3. The secondary battery 913 is provided at a position overlapping with the display portion 4005a, can have high density and high capacity, and is small and lightweight.

### Example 1

In this example, a secondary battery was fabricated and its characteristics were evaluated.

### <Formation of Positive Electrode Active Material>

A positive electrode active material was formed.

A commercial lithium cobalt oxide (Cellseed C-10N produced by Nippon Chemical Industrial Co., Ltd.) was prepared as lithium cobalt oxide. Next, the prepared lithium cobalt oxide was heated at 850° C. in an oxygen atmosphere for two hours.

Lithium fluoride and magnesium fluoride were weighed at a molar ratio of 1:3 and mixed to obtain a magnesium source. The magnesium source was weighed so that magnesium in the magnesium source can be 1 at % of cobalt in the lithium cobalt oxide, and was mixed with the heated lithium cobalt oxide to give a mixture A1.

Then, the mixture A1 was heated at 900° C. in an oxygen atmosphere for 20 hours to give a composite oxide B1.

Next, nickel hydroxide was prepared as a nickel source, and aluminum hydroxide was prepared as an aluminum source. The nickel source and the aluminum source were weighed so that nickel in the nickel hydroxide and aluminum in the aluminum hydroxide can each be 0.5 at % of cobalt in the composite oxide B1, and were mixed with the composite oxide B1 to give a mixture C1.

Then, the mixture C1 was heated at 850° C. in an oxygen atmosphere for 10 hours, and Sample Sa1 was fabricated.

### <Fabrication of Positive Electrode>

Sample Sa1, acetylene black (AB), polyvinylidene fluoride (PVDF), and NMP were mixed to form a slurry. The ratio of Sample Sa1, AB, and PVDF was 95:3:2 (weight ratio).

The obtained slurry was applied to one surface of an aluminum foil. After that, heat treatment was performed at 80° C., so that the NMP was volatilized. Pressing was performed after the heat treatment, so that a positive electrode was obtained.

### <Fabrication of Negative Electrode>

Graphite, VGCF (registered trademark), carboxymethyl cellulose sodium salt (CMC-Na), styrene butadiene rubber (SBR), and water were mixed to form a slurry. The ratio of graphite, VGCF, CMC-Na, and SBR was 96:1:1:2 (weight ratio).

The obtained slurry was applied to one surface of a copper foil. After that, heating was performed at 50° C., so that a negative electrode was obtained.

### <Fabrication of Secondary Battery>

A secondary battery was fabricated using the positive electrode and the negative electrode formed through the above steps. As a solvent of an electrolyte solution, a mixture of ethylene carbonate (EC) and diethyl carbonate (DEC) at EC:DEC=3:7 (volume ratio) was used. As a lithium salt, lithium hexafluorophosphate (LiPF₆) was used. The concentration of the lithium salt in the electrolyte solution was 1.00 mol/L. For the separator, polypropylene was used. As a film to be the exterior body, a film in which a polypropylene layer, an acid modified polypropylene layer, an aluminum layer, and a nylon layer were stacked in this order was used. First, one negative electrode having a negative electrode active material layer on one surface and one positive electrode having a positive electrode active material layer on one surface were prepared, and the negative electrode active material layer and the positive electrode active material layer were placed so as to face each other with a separator interposed therebetween.

Through the above steps, a secondary battery was fabricated.

<dQ/dV-V Curve>

A charge test was performed on the fabricated secondary battery used as a battery cell. In the secondary battery, four battery cells C1 to C4 connected in series were used. The ambient temperature in the measurement was set to 27° C., and as the charge conditions, a constant current charge was performed at 0.5 C and the charge termination voltage was set to 4.26 V.

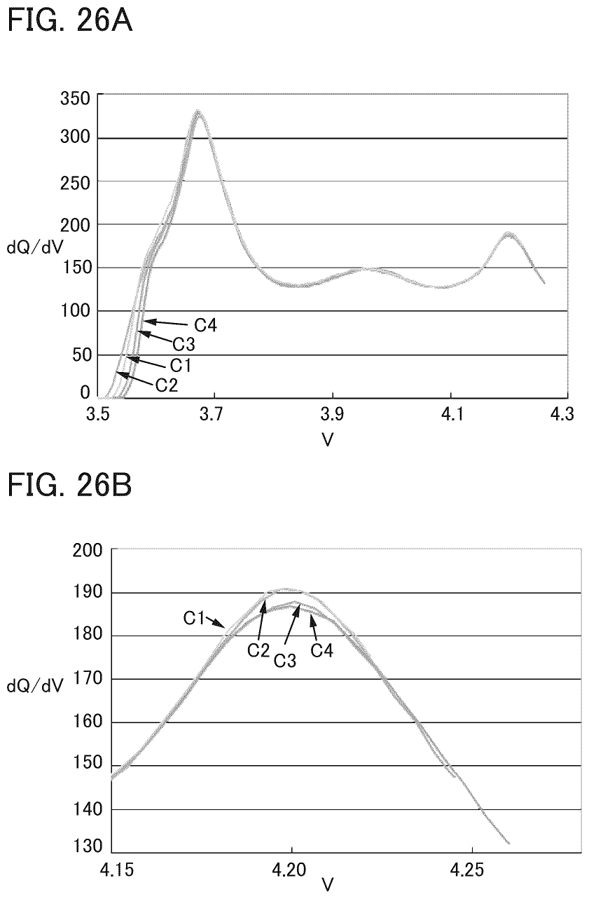

FIG. 26A shows dQ/dV-V curves in charge of the battery cells C1 to C4. FIG. 26B shows enlarged curves of the data in FIG. 26A at around 4.20 V. Note that in charge, data was obtained when the voltage was changed by 6 mV, i.e., when the amount of change in voltage was 6 mV. Note that the voltage measurement was performed every 100 ms, and data was obtained when the amount of change in voltage was 6 mV.

In charge, the dQ/dV-V curves of the battery cells C1 to C4 at 4.20 V peaked in the order of the battery cell C1, the battery cell C2, the battery cell C3, and the battery cell C4 in this order. The peak of the battery cell C2 was 140.7 seconds after the peak of the battery cell C1 reached. The peak of the battery cell C3 was 272.1 seconds after the peak of the battery cell C1 reached. The peak of the battery cell C4 was 333.8 seconds after the peak of the battery cell C1 reached. In consideration of the constant current charge, the difference in the amount of electricity between the battery cell C1 and the battery cell C2 was estimated to be 0.6036 mAh. The difference in the amount of electricity between the battery cell C1 and the battery cell C3 was estimated to be 1.1671 mAh. The difference in the amount of electricity between the battery cell C1 and the battery cell C4 was estimated to be 1.4312 mAh.

Cell balancing can be performed by discharging the battery cells C1, C2, and C3 in accordance with the battery cell C4 that finally reaches a peak. The discharge amount of the battery cell C1 was 1.4312 mAh, the discharge amount of the battery cell C2 was 1.14312-0.6036=0.8276 mAh, and the discharge amount of the battery cell C3 was 1.14312-1.1671=0.2641 mAh.

After that, the battery cell C1 and the battery cell C4 were charged with only 1.4312 mAh, whereby the full charge of the battery cell C1 to the battery cell C4 was completed.

<Notes on Description of this Specification and the Like>

The description of the above embodiments and each structure in the embodiments are noted below.

One embodiment of the present invention can be constituted by combining, as appropriate, the structure described in each embodiment with the structures described in the other embodiments. In the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

In the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values or the like shown in the drawings. For example, variations in a signal, a voltage, or a current due to noise, variations in a signal, a voltage, or a current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (or drain) terminal, a source (or drain) electrode, or the like as appropriate depending on the situation.

In this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms “film” and “layer” can be interchanged with each other depending on the case or situation. For example, the term “conductive layer” can be changed into the term “conductive film” in some cases. As another example, the term “insulating film” can be changed into the term “insulating layer” in some cases.

In this specification, a terminal refers to a portion for electrically connecting a battery, an IC, an FET element, or the like, and the shape of the terminal is not particularly limited. Any of terminals having various shapes such as a bolt shape, a wire shape, a flat plate shape, a ring shape, a socket shape, a pin shape, a solder hemispherical shape used for a BGA (Ball Grid Array), a flat plate shape used for an LGA (Land Grid Array), and a through-hole and a land (also referred to as a pad) of a printed wiring board can be used. Note that in a battery, part of the exterior body of the battery functions as a positive electrode terminal or a negative electrode terminal in some cases; in such a case, part of the exterior body of the battery can be used as a positive electrode terminal or a negative electrode terminal.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

In this specification and the like, “parallel” indicates a state where two straight lines are placed at an angle of greater than or equal to −10° and less than or equal to 10°, for example. Accordingly, the case where the angle is greater than or equal to −5° and less than or equal to 5° is also included. Moreover, “perpendicular” and “orthogonal” indicate a state where two straight lines are placed at an angle of greater than or equal to 80° and less than or equal to 100°, for example. Accordingly, the case where the angle is greater than or equal to 85° and less than or equal to 95° is also included.

In this specification and the like, the terms “identical”, “the same”, “equal”, “uniform”, and the like used in describing calculation values and actual measurement values allow for a margin of error of +20% unless otherwise specified.

In this specification and the like, segregation refers to a phenomenon in which in a solid made of a plurality of elements (e.g., A, B, and C), a certain element (e.g., B) is spatially non-uniformly distributed.

In this specification and the like, a surface portion of a particle of an active material or the like refers to a region ranging from the surface to a depth of approximately 10 nm, in a perpendicular direction or a substantially perpendicular direction from the surface toward the inner portion. Alternatively, the surface portion refers to a region within 50 nm from the surface. Alternatively, the surface portion refers to a region within 5 nm from the surface. The surface portion is synonymous with the vicinity of a surface, a region in the vicinity of a surface, or a shell. Note that “substantially perpendicular” refers to a state where an angle is greater than or equal to 80° and less than or equal to 100°. A plane generated by a fissure or a crack can be considered as a surface. A region at a position deeper than the surface portion is referred to as an inner portion. The surface of the positive electrode active material in EDX line analysis or the like refers to a measurement point showing a measurement value which is closest to 50% of the average value of the detection amount of the transition metal in bulk. Alternatively, the surface is an intersecting point between a tangent drawn by a tangent method to an intensity profile of the transition metal obtained by EDX line analysis and an axis in the depth direction. The surface of the positive electrode active material in, for example, a STEM image is a boundary between a region where an image derived from the crystal structure of the positive electrode active material is observed and a region where the image is not observed, and is determined as the outermost surface of a region where an atomic column derived from an atomic nucleus of a metal element that has a larger atomic number than lithium. Alternatively, the surface refers to an intersection of a tangent drawn to a luminance profile from the surface toward the bulk and an axis in the depth direction in a STEM image. The surface in a STEM image or the like may be judged in combination with analysis with higher spatial resolution.

In this specification and the like, a layered rock-salt crystal structure of a composite oxide containing lithium and a transition metal refers to a crystal structure in which a rock-salt ion arrangement where cations and anions are alternately arranged is included and the transition metal and lithium are regularly arranged to form a two-dimensional plane, so that lithium can be two-dimensionally diffused. Note that a defect such as a cation or anion vacancy may be included. In the layered rock-salt crystal structure, strictly, a lattice of a rock-salt crystal is distorted in some cases.

In this specification and the like, a rock-salt crystal structure refers to a structure in which cations and anions are alternately arranged. Note that a cation or anion vacancy may be included.

In this specification and the like, an O3′ type crystal structure (also referred to as a pseudo-spinel crystal structure) of a composite oxide containing lithium and a transition metal refers to a crystal structure with a space group R-3m, which is not a spinel crystal structure but a crystal structure in which an ion of cobalt, magnesium, or the like is coordinated to six oxygen atoms and the cation arrangement has symmetry similar to that of the spinel crystal structure. Note that in the O3′ type crystal structure, a light element such as lithium occupies a site coordinated to four oxygen atoms in some cases. Also in that case, the ion arrangement has symmetry similar to that of the spinel crystal structure.

The O3′ type crystal structure can be regarded as a crystal structure that contains Li between layers randomly but is similar to a CdCl₂ type crystal structure. The crystal structure similar to the CdCl₂ type crystal structure is close to a crystal structure of lithium nickel oxide that is charged to be Li_{0.06}NiO₂; however, pure lithium cobalt oxide or a layered rock-salt positive electrode active material containing a large amount of cobalt is known not to have this crystal structure generally.

Anions of a layered rock-salt crystal and anions of a rock-salt crystal form a cubic close-packed structure (face-centered cubic lattice structure). Anions of an O3′ type crystal are also presumed to form a cubic close-packed structure. When these crystals are in contact with each other, there is a crystal plane at which orientations of cubic close-packed structures composed of anions are aligned. Note that a space group of the layered rock-salt crystal and the O3′ type crystal is R-3m, which is different from the space group Fm-3m of a rock-salt crystal (a space group of a general rock-salt crystal) and the space group Fd-3m of a rock-salt crystal (a space group of a rock-salt crystal having the simplest symmetry); thus, the Miller index of the crystal plane satisfying the above conditions in the layered rock-salt crystal and the O3′ type crystal is different from that in the rock-salt crystal. In this specification, in the layered rock-salt crystal, the O3′ type crystal, and the rock-salt crystal, a state where the orientations of the cubic close-packed structures formed of anions are aligned with each other may be referred to as a state where crystal orientations are substantially aligned with each other.

A secondary battery includes a positive electrode and a negative electrode, for example. A positive electrode active material is a material included in the positive electrode. The positive electrode active material is a substance that performs a reaction contributing to the charge and discharge capacity, for example. Note that the positive electrode active material may partly contain a substance that does not contribute to the charge and discharge capacity.

In this specification and the like, the positive electrode active material used in one embodiment of the present invention is expressed as a positive electrode material or a secondary battery positive electrode material in some cases. In this specification and the like, the positive electrode active material used in one embodiment of the present invention preferably includes a compound. In this specification and the like, the positive electrode active material used in one embodiment of the present invention preferably includes a composition. In this specification and the like, the positive electrode active material used in one embodiment of the present invention preferably includes a complex.

In this specification and the like, crystal planes and orientations are indicated by the Miller index. An individual plane that shows a crystal plane is denoted by “( )”. In the crystallography, a bar is placed over a number in the expression of crystal planes, crystal orientations, and space groups; however, in this specification and the like, because of format limitations, crystal planes, crystal orientations, and space groups are sometimes expressed by placing—(a minus sign) at the front of a number instead of placing a bar over the number. Furthermore, an individual direction which shows an orientation in a crystal is denoted with “[ ]”, a set direction which shows all of the equivalent orientations is denoted with “< >”, an individual plane which shows a crystal plane is denoted with “( )”, and a set plane having equivalent symmetry is denoted with “{ }”. A trigonal system represented by the space group R-3m is generally represented by a composite hexagonal lattice for easy understanding of the structure and, in some cases, not only (hkl) but also (hkil) is used as the Miller index. Here, i is −(h+k). In this specification and the like, the theoretical capacity of a positive electrode active material refers to the amount of electricity for the case where lithium that can be inserted and extracted in the positive electrode active material is all extracted. For example, the theoretical capacity of LiCoO₂ is 274 mAh/g, the theoretical capacity of LiNiO₂ is 274 mAh/g, and the theoretical capacity of LiMn₂O₄ is 148 mAh/g.

In this specification and the like, a charge depth is a value indicating the degree of a capacity that has been charged, i.e., the amount of lithium extracted from a positive electrode, relative to the theoretical capacity of a positive electrode active material as reference. For example, in the case of a positive electrode active material having a layered rock-salt structure such as lithium cobalt oxide (LiCoO₂) or lithium nickel cobalt manganese oxide (LiNiₓCo_{y}Mn_{z}O₂ (x+y+z=1)), a charge depth of 0 indicates a state where no Li has been extracted from the positive electrode active material; a charge depth of 0.5 indicates a state where lithium corresponding to 137 mAh/g has been extracted from the positive electrode; and a charge depth of 0.8 indicates a state where lithium corresponding to 219.2 mAh/g has been extracted from the positive electrode, relative to the theoretical capacity of 274 mAh/g as reference. In the case where an expression LiₐCoO₂ (0≤a≤1) is used, LiₐCoO₂ is LiCoO₂ where a is 1 when the charge depth is 0; LiₐCoO₂ is Li_{0.5}CoO₂ where a is 0.5 when the charge depth is 0.5; and LiₐCoO₂ is Li_{0.2}CoO₂ where a is 0.2 when the charge depth is 0.8.

### REFERENCE NUMERALS

10: secondary battery, 11: battery cell, 20: charge/discharge control switch, 31: current measurement circuit, 32: voltage measurement circuit, 33: control portion, 34: memory, 35: discharger, 36: resistor, 37: cell balance control switch, 38: subtractor, 80: load, 81: discharge switch, 90: charger, 91: charge switch, 100: charge management system

1. A charge management system of a secondary battery comprising:
the secondary battery comprising a first battery cell and a second battery cell which are connected in series;
a current measurement circuit configured to measure current flowing through the first battery cell and the second battery cell in charge of the secondary battery;
a voltage measurement circuit configured to measure a voltage of each of the first battery cell and the second battery cell in charge of the secondary battery; and
a control circuit configured to perform control for making a charge rate of the first battery cell equal to a charge rate of the second battery cell,
wherein the control circuit is configured to calculate data exhibiting battery characteristics in accordance with current data and voltage data measured in each of the first battery cell and the second battery cell, and
wherein the control for making the charge rate of the first battery cell equal to the charge rate of the second battery cell is performed by controlling the charge rates so that local maximum values of the data exhibiting battery characteristics are equal to each other.

2. The charge management system of the secondary battery according to claim 1,
wherein the local maximum values of the data exhibiting battery characteristics are obtained when a vertical axis is dQ/dV representing an amount of change in an amount of electricity with respect to an amount of change in voltage and a horizontal axis is cumulative capacity.

3. The charge management system of the secondary battery according to claim 1,
wherein the local maximum values of the data exhibiting battery characteristics are obtained when a vertical axis is dt/dV representing an amount of change in time with respect to an amount of change in voltage and a horizontal axis is time.

4. The charge management system of the secondary battery according to claim 1,
wherein the secondary battery is charged at a constant current.
